(19) United States
(12) Patent Application Publication
(10) Pub. No.: US 2026/0372072 A1
(43) Pub. Date: Nov. 19, 2026

(54) SEMICONDUCTOR DEVICE, MANUFACTURING METHOD THEREFOR, HEAT RADIATING FILM FORMING METHOD, AND WIRING STRUCTURE

(71) Applicant: The University of Tokyo, Tokyo (JP)

(72) Inventors: Takeshi TAKAGI, Tokyo (JP); Takeki NINOMIYA, Tokyo (JP); Masaaki NIWA, Tokyo (JP); Masahiro NOMURA, Tokyo (JP)

(21) Appl. No.: 19/136,450

(22) PCT Filed: Dec. 8, 2023
(86) PCT No.: PCT/JP2023/044078

§ 371 Date: Sep. 17, 2025

(30) Foreign Application Priority Data
Dec. 9, 2022 (JP) 2022-196861

(51) Int. Cl. H10W 40/22; H10W 20/40; H10W 20/41; H10W 40/25; H10W 70/60; H10W 90/20; H10W 90/26

(52) U.S. Cl. CPC H10W 40/22; H10W 20/427; H10W 20/496; H10W 40/259; H10W 70/618; H10W 90/26; H10W 90/288

(57) ABSTRACT

A wiring structure of the present invention includes: one or more wiring layers provided on a base substrate and disposed between the base substrate and a semiconductor chip, or formed on the semiconductor chip, in which a wiring in the wiring layers is electrically connected to an element of the semiconductor chip, and the wiring structure includes one or more of the wiring layers in which a wiring portion including the wiring is formed in a wiring layer insulating film made of AlN or BN.

### TECHNICAL FIELD

The present invention relates to a semiconductor device, a manufacturing method therefor, a heat dissipation film forming method, and a wiring structure.

### BACKGROUND ART

In recent years, an integration density has been improved by forming a stacked structure in which a plurality of semiconductor chips are stacked in a thickness direction thereof. There are known a semiconductor device that improves the heat dissipation property of the stacked structure as described above by using a through Si via (TSV) electrically connected to a wiring in a wiring layer of a semiconductor chip, and a semiconductor device that improves the heat dissipation property of the stacked structure by using a structure called a thermal via (via for thermal conduction), a thermal TSV, or the like having a through structure that is not electrically connected to the wiring in the wiring layer but penetrates the stacked structure similar to the through Si via (see PTLs 1 and 2). For example, in the semiconductor device described in PTL 1, the through Si via and the thermal via are provided, and both have a structure in which an electrode material, for example, copper (Cu) is embedded in a through hole provided in each of semiconductor chips so as to penetrate the stacked structure, and an insulating film made of SiO₂ is interposed between the electrode material and each of the semiconductor chips.

### CITATION LIST

### Patent Literature

PTL 1: WO2010/119570

PTL 2: JP2016-72626A

### SUMMARY OF INVENTION

### Technical Problem

The above-described through Si via and the thermal via have high thermal conductivity in the stacking direction of the semiconductor chips. However, the heat conduction from a silicon layer in which transistors and the like serving as heat generation sources of the respective semiconductor chips are present to the through Si via or the thermal via is insufficient, and thus sufficient heat dissipation property cannot be obtained.

An object of the present invention is to provide a semiconductor device capable of further improving heat dissipation property, a manufacturing method therefor, a heat dissipation film forming method, and a wiring structure.

### Solution to Problem

A semiconductor device of the present invention includes: a semiconductor chip including a semiconductor substrate having a silicon layer, an insulating film made of a film material of AlN or BN and provided on an inner wall surface of a hole in the silicon layer, the hole penetrating the semiconductor substrate in a thickness direction or having a bottom, and a thermal conductor made of a thermal conductive material and provided in the hole with the insulating film sandwiched between the thermal conductor and the silicon layer.

A method for manufacturing a semiconductor device of the present invention includes: a hole forming step of forming a hole that penetrates in a thickness direction or has a bottom in a semiconductor substrate having a silicon layer of a semiconductor chip; an insulating film forming step of forming an insulating film of AlN or BN, on an inner wall surface of the hole in the silicon layer; and a thermal conductor forming step of forming a thermal conductor of a thermal conductive material, in the hole with the insulating film sandwiched between the thermal conductor and the silicon layer.

A semiconductor device of the present invention includes: a semiconductor chip including a semiconductor substrate having a silicon layer, and a heat dissipation film made of a film material of AlN or BN and provided on a side wall surface of the semiconductor substrate.

A semiconductor device of the present invention includes: a semiconductor chip including a semiconductor substrate having a silicon layer, and a heat dissipation film made of any film material of Al₂O₃, Si₃N₄, or a composite material obtained by mixing AlN and Si₃N₄ and provided on a side wall surface of the semiconductor substrate.

A method for manufacturing a semiconductor device of the present invention includes: a chip body step of providing, on a base semiconductor chip, a chip body including one layer of semiconductor chip or a chip body in which two or more layers of semiconductor chips are stacked; and a heat dissipation film forming step of forming a heat dissipation film using a film material of AlN or BN on surfaces of the base semiconductor chip and the chip body by using an aerosol deposition method, a cold spray method, or a supersonic free jet PVD method.

A method for manufacturing a semiconductor device of the present invention includes: a chip body step of providing, on a base semiconductor chip, a chip body including one layer of semiconductor chip or a chip body in which two or more layers of semiconductor chips are stacked; and a heat dissipation film forming step of forming a heat dissipation film using any film material of Al₂O₃, Si₃N₄, or a composite material obtained by mixing AlN and Si₃N₄, on surfaces of the base semiconductor chip and the chip body by using an aerosol deposition method.

A method for manufacturing a semiconductor device of the present invention includes: a heat dissipation film forming step of forming, on a base semiconductor chip on which a chip body including one layer of semiconductor chip or a chip body in which two or more layers of semiconductor chips are stacked is provided, a heat dissipation film which is made of AlN and in which the chip body is embedded, and planarizing a surface of the heat dissipation film; a bonding layer forming step of forming a Si bonding layer on the surface of the heat dissipation film and planarizing a surface of the bonding layer; and an activation bonding step of activating a surface of a heat spreader made of silicon and the surface of the bonding layer, respectively, and bonding both the surfaces to each other.

A method for manufacturing a semiconductor device of the present invention is a heat dissipation film forming method for forming a heat dissipation film on a base semiconductor chip in which one or more chip bodies each including one layer of semiconductor chip or one or more chip bodies each including two or more layers of stacked semiconductor chips are provided on a substrate surface, the method including: controlling, based on a layout of the chip bodies on the substrate surface, a relative movement of the base semiconductor chip and a nozzle that sprays, toward the substrate surface, an aerosol in which raw material fine particles for forming the heat dissipation film are dispersed in a carrier gas, such that the aerosol is sprayed mainly onto one or both of a region around the semiconductor chip and a region between the adjacent chip bodies, and forming the heat dissipation film in which the raw material fine particles are deposited around the chip bodies.

A wiring structure of the present invention includes: one or more wiring layers provided on a base substrate and disposed between the base substrate and a semiconductor chip, or formed on the semiconductor chip, in which a wiring in the wiring layers electrically connected to an element of the semiconductor chip, and the wiring structure includes one or more of the wiring layers in which a wiring portion including the wiring is formed in a wiring layer insulating film made of AlN or BN.

A semiconductor device of the present invention includes: a first semiconductor substrate including a multi-layer wiring layer, a first bonding insulating film made of AlN on an uppermost layer of the multi-layer wiring layer, and a first electrode pad formed on a surface of the first bonding insulating film; and a second semiconductor substrate including a second bonding insulating film made of AlN and a second electrode pad formed on a surface of the second bonding insulating film, the first bonding insulating film being directly bonded to the second bonding insulating film and the first electrode pad being directly bonded to the second electrode pad.

A semiconductor device of the present invention includes: a silicon substrate including an element layer on a surface thereof; a multi-layer wiring layer formed on the element layer and including a wiring provided in a wiring layer insulating film made of AlN; a power supply wiring layer formed on a back surface of the silicon substrate and including a power supply wiring provided in the wiring layer insulating film; a bonding layer formed on the multi-layer wiring layer; and a Si carrier directly bonded to the bonding layer, in which one or both of the wiring layer insulating film and the bonding layer are made of AlN.

A method for manufacturing a semiconductor device of the present invention includes: forming a bonding layer of AlN on a surface of a wiring layer insulating film of a multi-layer wiring layer provided on a semiconductor chip; and directly bonding a surface of the bonding layer and a surface of a Si carrier after being activated.

### Advantageous Effects of Invention

According to the semiconductor device of the present invention, the insulating film made of AlN or BN is provided in the semiconductor chip on the inner wall surface of the hole in the silicon layer, the hole penetrating the semiconductor substrate in the thickness direction or having the bottom, and thus the heat dissipation property of the semiconductor device is improved.

According to the method for manufacturing a semiconductor device of the present invention, the insulating film is made of AlN or BN, and formed on the inner wall surface of the hole in the silicon layer, the hole penetrating in the thickness direction or having the bottom in the semiconductor substrate having the silicon layer of the semiconductor chip, and the thermal conductor made of the thermal conductive material is formed in the hole with the insulating film sandwiched between the thermal conductor and the silicon layer, and thus the semiconductor device with improved heat dissipation property is obtained.

According to the semiconductor device of the present invention, the heat dissipation film made of AlN or BN, or Al₂O₃, Si₃N₄, or a composite material obtained by mixing AlN and Si₃N₄ is provided in the semiconductor chip on the side wall surface of the semiconductor substrate having the silicon layer, thereby improving the heat dissipation property of the semiconductor device.

According to the method for manufacturing a semiconductor device of the present invention, the heat dissipation film is made of any film material of AlN or BN, or Al₂O₃, Si₃N₄, or a composite material obtained by mixing AlN and Si₃N₄, on the surface of the chip body including one layer of semiconductor chip or the chip body in which two or more layers of semiconductor chips are stacked and the surface of the base semiconductor chip provided with the chip body, and thus the heat of the silicon layer is transferred to the insulating film, and the heat dissipation property of the semiconductor device is improved.

According to the method for manufacturing a semiconductor device of the present invention, the heat dissipation film made of AlN and the Si heat spreader are directly bonded via the Si bonding layer, and thus the heat of the semiconductor chip can be efficiently transferred to the heat spreader, resulting in a semiconductor device with high heat dissipation property.

According to the heat dissipation film forming method of the present invention, the relative movement between the nozzle and the base semiconductor chip is controlled based on the layout of the chip bodies such that the aerosol in which the raw material fine particles are dispersed is sprayed mainly onto the region around the semiconductor chip and the region between adjacent chip bodies, thereby efficiently forming the heat dissipation film.

According to the wiring structure of the present invention, the wiring layer insulating film in the wiring layer is made of AlN or BN, and thus the heat is transferred to the wiring layer insulating film, and the heat dissipation property can be further improved.

According to the semiconductor device of the present invention, the first bonding insulating film made of AlN having high thermal conductivity on the uppermost layer of the multi-layer wiring layer and the first electrode pad formed on the surface of the first bonding insulating film are directly bonded to the second bonding insulating film made of AlN on the second semiconductor substrate and the second electrode pad, respectively, and thus the heat dissipation property is improved.

According to the semiconductor device of the present invention, when one or both of the bonding layer formed on the multi-layer wiring layer provided on the silicon substrate and directly bonded with the Si carrier and the wiring layer insulating film of the power supply wiring layer formed on the back surface of the silicon substrate are made of AlN, and thus the heat dissipation property can be improved.

According to the method for manufacturing a semiconductor device of the present invention, the bonding layer is made of AlN on the multi-layer wiring layer provided on the semiconductor chip, and the bonding layer and the Si carrier are directly bonded to each other, and thus a semiconductor device with high heat dissipation property can be obtained.

### BRIEF DESCRIPTION OF DRAWINGS

FIG. 1 is a cross-sectional view illustrating a configuration of a semiconductor device according to a first embodiment.

FIG. 2 is a cross-sectional view illustrating an insulating film in a silicon layer and a wiring layer.

FIG. 3 is a diagram illustrating bonding of a chip stacked body having a heat transfer portion formed thereon to a base substrate.

FIG. 4 is a diagram illustrating an example of preparing a chip stacked body by stacking semiconductor chips on which chip heat transfer portions are formed.

FIG. 5 is a cross-sectional view illustrating an example in which a thermal conductor is electrically connected to a wiring in a wiring layer to form a through-silicon via.

FIG. 6 is a cross-sectional view illustrating an example in which an intermediate film is provided between the thermal conductor and an insulating film.

FIG. 7A is a diagram illustrating a temperature distribution according to a simulation of the semiconductor device in which a semiconductor chip and an insulating film of the heat transfer portion of the base substrate are made of AlN.

FIG. 7B is a diagram illustrating a temperature distribution according to a simulation of the semiconductor device in which the semiconductor chip and the insulating film of the heat transfer portion of the base substrate are made of SiO₂.

FIG. 7C is a diagram illustrating a temperature distribution according to a simulation of the semiconductor device in which the insulating film of the heat transfer portion of the semiconductor chip is made of SiO₂, and the insulating film of the heat transfer portion of the base substrate is made of AlN.

FIG. 8 is a diagram illustrating a semiconductor device according to a second embodiment.

FIG. 9 is a diagram illustrating an example of manufacturing the semiconductor device by forming a heat dissipation film in a state in which a plurality of chip stacked bodies are bonded to a surface of a wafer.

FIG. 10A is a diagram illustrating a temperature distribution according to a simulation of the semiconductor device provided with an AlN heat dissipation film.

FIG. 10B is a diagram illustrating a temperature distribution according to a simulation of the semiconductor device provided with a SiO₂ heat dissipation film.

FIG. 11 is a perspective view illustrating an example in which a heat dissipation film, which is provided on a base substrate and in which a semiconductor chip is embedded, is made of AlN or BN.

FIG. 12 is a diagram illustrating an example in which reconstruction layers are stacked.

FIG. 13 is a diagram illustrating an example of the semiconductor device in which a side surface of the semiconductor chip is used as an inclined surface, and a heat dissipation film is provided.

FIG. 14 is a diagram illustrating an example of the semiconductor device in which the side surface of the semiconductor chip is used as an inclined surface, and a heat dissipation film having a two-layer structure is provided.

FIG. 15 is a diagram illustrating an example of the semiconductor device in which the side surface of the semiconductor chip is used as an inclined surface, and an upper surface of the semiconductor chip is covered with the heat dissipation film having a two-layer structure.

FIG. 16 is a diagram illustrating an example in which a silicon heat spreader is attached to the heat dissipation film made of AlN.

FIG. 17 is a perspective view illustrating an example of a film forming device in which a nozzle that sprays aerosol and a base substrate to which the semiconductor chip is fixed are moved relatively based on a layout of the semiconductor chip.

FIG. 18 is a diagram illustrating an example of a film forming procedure using the film forming device.

FIG. 19 illustrates an example in which an interlayer insulating film in an upper layer portion of a multi-layer wiring layer of a semiconductor chip is made of AlN according to a third embodiment.

FIG. 20 is a diagram illustrating an example in which a low dielectric constant insulating film is provided between the interlayer insulating film and a wiring portion.

FIG. 21 is a diagram illustrating an example in which the interlayer insulating film is made of AlN and hybrid bonding is performed.

FIG. 22 is a cross-sectional view illustrating an example in which an interlayer insulating film of a multi-layer wiring layer of a silicon interposer is made of AlN.

FIG. 23 is a cross-sectional view illustrating an example in which an interlayer insulating film of a multi-layer wiring layer of a silicon bridge is made of AlN.

FIG. 24 is a cross-sectional view illustrating an example in which an interlayer insulating film of a multi-layer wiring layer on a build-up substrate is made of AlN.

FIG. 25 is a cross-sectional view illustrating an example in which a wiring layer insulating film in a power supply wiring layer provided on a back surface of the semiconductor chip is made of AlN.

FIG. 26 is a cross-sectional view illustrating an example in which a power supply wiring layer is provided on the back surface of the semiconductor chip provided on the interposer.

FIG. 27 is a cross-sectional view illustrating an example in which a dielectric layer of a MIM capacitor in the power supply wiring layer is made of AlN.

FIG. 28 is a diagram illustrating a layer structure of the semiconductor device of an example in which a heat dissipation effect is enhanced by forming a bonding layer and the wiring layer insulating film of the power supply wiring layer of AlN.

FIG. 29 is a graph illustrating peak temperatures of the semiconductor device in a simulation in which thermal conductivities of the bonding layer and the wiring layer insulating film were changed.

FIG. 30 is a graph illustrating a distribution of the peak temperatures in a vertical direction and a horizontal direction for each of the thermal conductivities in the simulation in which the thermal conductivity of the bonding layer was changed.

FIG. 31 is a graph illustrating a distribution of the peak temperatures in the vertical direction and the horizontal direction for each of the thermal conductivities in the simulation in which the thermal conductivity of the wiring layer insulating film was changed.

FIG. 32 is a graph illustrating a distribution of the peak temperatures in the vertical direction and the horizontal direction in a simulation in which the thermal conductivities of the bonding layer and the wiring layer insulating film were changed.

### DESCRIPTION OF EMBODIMENTS

### First Embodiment

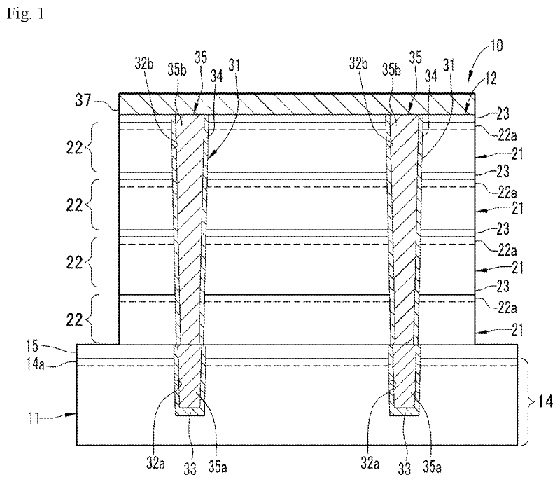

FIG. 1 illustrates a semiconductor device 10 according to an embodiment. The semiconductor device 10 includes a base substrate 11 and a chip stacked body 12. The base substrate 11 is a semiconductor substrate and includes a silicon layer 14 and a multi-layer wiring layer 15 on the silicon layer 14. The silicon layer 14 is formed with, on an upper layer portion thereof, an element layer 14a including active regions to be a drain, a source, and a channel region of a transistor. The element layer 14a and the multi-layer wiring layer 15 constitute a device layer. The multi-layer wiring layer 15 is implemented by a plurality of stacked wiring layers. The wiring layers of the multi-layer wiring layer 15 include an interlayer insulating film that electrically insulates wirings of the layers and wirings within the same layer, a wiring formed in the interlayer insulating film, vias or contacts that electrically connect the wirings of different layers, and the like. Examples of the wiring include a signal wiring such as a gate wiring for transmitting a signal of the element layer 14a and a power supply wiring for supplying power. The interlayer insulating film is made of, for example, silicon oxide.

The chip stacked body 12 is obtained by stacking a plurality of semiconductor chips 21 in a thickness direction thereof. Similar to the base substrate 11, each of the semiconductor chips 21 has a configuration in which a multi-layer wiring layer 23 is provided on a silicon layer 22 of the semiconductor substrate, and an element layer 22a is formed in an upper layer portion of the silicon layer 22. Each of the semiconductor chips 21 is thinned by polishing the silicon layer 22. The element layer 22a and the multi-layer wiring layer 23 constitute a device layer. The chip stacked body 12 is fixed to one substrate surface of the base substrate 11, in this example, a surface on a multi-layer wiring layer 15 side. The number of stacked semiconductor chips 21 in the chip stacked body 12 is not limited. In FIG. 1, the hatching of cross sections of the base substrate 11 and the semiconductor chip 21 is omitted in order to avoid complication of the drawing. The same applies to the other drawings. In addition, the up and down will be described based on an up-down direction illustrated in FIG. 1, and an orientation, posture, and the like of the semiconductor device 10 are not limited thereto.

For example, a circuit on the base substrate 11 is a GPU, an MPU, or the like, and each of the semiconductor chips 21 of the chip stacked body 12 is a memory element from and to which data is read and written by the circuit of the base substrate 11. In such a configuration, a logic operation circuit is formed in a device layer of the base substrate 11, and a large number of memory cells are formed in a device layer of each of the semiconductor chips 21. The wiring of the multi-layer wiring layer 15 of the base substrate 11 and a wiring of the multi-layer wiring layer 23 of each of the semiconductor chips 21 are electrically connected by a plurality of through-silicon vias (TSVs) (not illustrated) that penetrates the chip stacked body 12 in the stacking direction of the semiconductor chips 21. The multi-layer wiring layer 23 has the same configuration as the multi-layer wiring layer 15. In this example, a base semiconductor substrate on which a semiconductor circuit is formed as described above is used as the base substrate 11, but the base substrate 11 is not limited thereto and may be, for example, an interposer including a silicon interposer.

The semiconductor device 10 is provided with a plurality of heat transfer portions 31. In FIG. 1, a size of the heat transfer portion 31 is exaggerated. Although two heat transfer portions 31 are illustrated in FIG. 1, the number of heat transfer portions 31 is not limited, and may be one or three or more. It is preferable to provide a larger number of heat transfer portions 31 from the viewpoint of enhancing the heat dissipation property. The heat transfer portion 31 includes a hole 32a, a through hole 32b, insulating films 33 and 34, and a thermal conductor 35.

The hole 32a is formed as a bottomed hole in the base substrate 11. The hole 32a is formed at a depth equal to or larger than a thickness of the device layer from the multi-layer wiring layer 15 side. That is, the base substrate 11 is provided to enter the element layer 14a of the silicon layer 14 serving as a heat source. The through hole 32b is provided in the chip stacked body 12 and penetrates the chip stacked body 12 in the stacking direction of the semiconductor chips 21. The through hole 32b is connected to the hole 32a at a lower end thereof.

The insulating film 33 is formed on an inner wall surface of the hole 32a, and the insulating film 34 is formed on an inner wall surface of the through hole 32b. The hole 32a has a bottom, and thus the insulating film 33 is formed at the bottom as well as an inner peripheral surface of the hole 32a. In addition, the through hole 32b has no bottom, and thus the insulating film 34 is formed at an inner peripheral surface of the through hole 32b. Accordingly, the insulating films 33 and 34 electrically insulate the silicon layers 14 and 22 having the conductivity from the thermal conductor 35 provided in the holes 32a and through holes 32b.

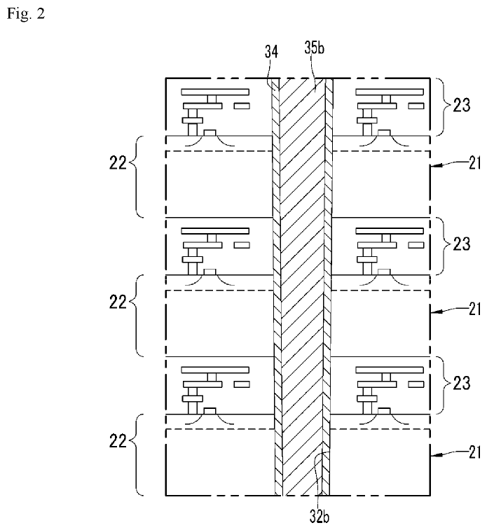

In this example, as illustrated in FIG. 2, the insulating film 34 is continuously formed on the inner wall surface of the through hole 32b in the stacking direction of the semiconductor chips 21. Therefore, the insulating film 34 is also formed on the inner peripheral surface of a portion of the through hole 32b passing through the silicon layer 22 and the inner peripheral surface of a portion of the through hole 32b passing through the multi-layer wiring layer 23. In the base substrate 11, the insulating film 33 is also formed on the inner peripheral surface of a portion of the hole 32a passing through the silicon layer 14 and the inner peripheral surface of a portion of the hole 32a passing through the multi-layer wiring layer 15.

The thermal conductor 35 includes a base-side thermal conductor 35a provided in the hole 32a and a stacked body-side thermal conductor 35b serving as a through thermal conductor provided in the through hole 32b. For example, when the base substrate 11 and the chip stacked body 12 are bonded to each other, the base-side thermal conductor 35a and the stacked body-side thermal conductor 35b are integrated into one body to form the thermal conductor 35 by bonding bonding pads formed on end portions of the base-side thermal conductor 35a and the stacked body-side thermal conductor 35b.

The base-side thermal conductor 35a is embedded in a space surrounded by the insulating film 33 in the hole 32a, and the stacked body-side thermal conductor 35b is embedded in a space surrounded by the insulating film 34 in the through hole 32b. That is, the base-side thermal conductor 35a is provided in the hole 32a with the insulating film 33 sandwiched between the base-side thermal conductor 35a and the silicon layer 14, and the base-side thermal conductor 35a is electrically insulated from the silicon layer 14 by the insulating film 33. In addition, the stacked body-side thermal conductor 35b is provided in the through hole 32b with the insulating film 34 sandwiched between the stacked body-side thermal conductor 35b and the silicon layer 22, and the stacked body-side thermal conductor 35b is electrically insulated from the silicon layer 22 by the insulating film 34.

Both the base-side thermal conductor 35a and the stacked body-side thermal conductor 35b are made of a thermal conductive material having high thermal conductivity, such as copper (Cu) in this example. Examples of preferable materials for the base-side thermal conductor 35a and the stacked body-side thermal conductor 35b include tungsten (W), ruthenium (Ru), and cobalt (Co) in addition to Cu.

The hole 32a, the through hole 32b, the base-side thermal conductor 35a, and the stacked body-side thermal conductor 35b can be formed using a well-known semiconductor process.

In the heat transfer portion 31 configured as described above, the insulating films 33 and 34 are made of aluminum nitride (AlN) having the electrical insulating property and high thermal conductivity. Accordingly, the heat from the element layers 14a and 22a is effectively transferred to the thermal conductor 35. The insulating films 33 and 34 are formed by being deposited in the hole 32a and the through hole 32b by using, for example, an atomic layer deposition (ALD) method and then etching central portions thereof. The insulating films 33 and 34 may be made of boron nitride (BN) instead of AlN.

As illustrated in FIG. 1, a heat sink 37 is provided on an upper surface of the chip stacked body 12. The heat sink 37 has a lower surface bonded to an upper end of the thermal conductor 35, and dissipates the heat transmitted from the thermal conductor 35 to the outside. In this example, the heat sink 37 has a plate shape spreading over the entire upper surface of the chip stacked body 12 to increase a surface area, thereby reducing a thermal resistance and effectively dissipating the heat. The heat sink 37 is electrically insulated from the chip stacked body 12 by, for example, a protective layer (not illustrated) provided on an upper layer of the multi-layer wiring layer 23 of the uppermost semiconductor chip 21. In addition, a thermal interface material (TIM) such as a thermal conductive grease, a thermal conductive adhesive, and a thermal conductive sheet may be provided on the upper surface of the chip stacked body 12, and the heat from the thermal conductor 35 may be transferred to the heat sink 37 via the thermal interface material.

The base substrate 11 is one of the semiconductor chips, and a structure in which the base substrate 11 and the plurality of semiconductor chips 21 are stacked can also be regarded as a chip stacked body. Therefore, when the entire semiconductor device 10 is a chip stacked body, the base substrate 11 is a semiconductor chip in a first layer, and the plurality of semiconductor chips 21 constituting the chip stacked body 12 are semiconductor chips in a second layer or more. In this way, when the semiconductor device 10 is regarded as a chip stacked body, the base-side thermal conductor 35a of the base substrate 11 that is the semiconductor chip in the first layer of this example transfers the heat only toward the stacked body-side thermal conductor 35b on a chip stacked body 12 side, and thus does not penetrate the base substrate 11 with the hole 32a having a bottom. For example, as in the case in which the base substrate 11 is an interposer, a hole that penetrates the semiconductor chip in the first layer (base substrate 11) may be provided, and the base-side thermal conductor 35a may penetrate the base substrate 11.

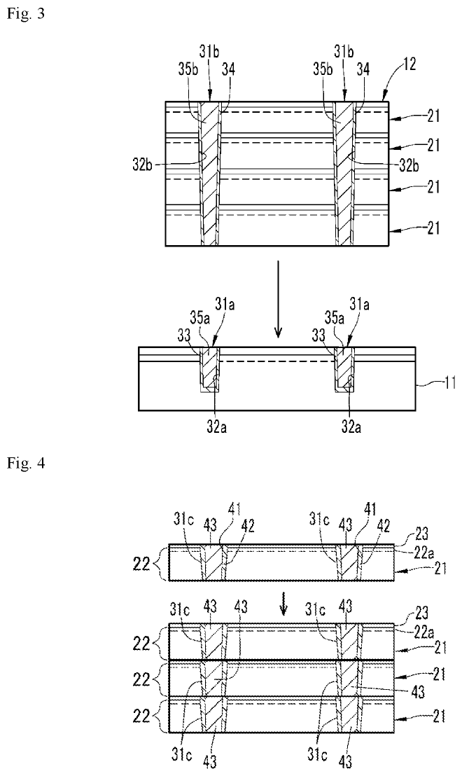

In this example, as illustrated in FIG. 3, a base-side heat transfer portion 31a on a base substrate 11 side of the heat transfer portion 31 and a stacked body-side heat transfer portion 31b on the chip stacked body 12 side are formed before the base substrate 11 and the chip stacked body 12 are bonded to each other, and then the base substrate 11 and the chip stacked body 12 are bonded to each other. That is, the chip stacked body 12 obtained by stacking the plurality of semiconductor chips 21 is formed, and the through hole 32b that penetrates the chip stacked body 12 is formed in the chip stacked body 12. Then, the insulating film 34 is formed on the inner wall surface (inner peripheral surface) of the through hole 32b, and the stacked body-side thermal conductor 35b is further formed to provide the stacked body-side heat transfer portion 31b in the chip stacked body 12. Then, the chip stacked body 12 provided with the stacked body-side heat transfer portion 31b is bonded to the base substrate 11 provided with the base-side heat transfer portion 31a.

The base substrate 11 and the chip stacked body 12 can be bonded to each other and the semiconductor chips 21 of the chip stacked body 12 can be bonded to each other by using a well-known bonding technique. Preferably, the bonding is fusion bonding in which the insulating films are directly bonded to each other, or a hybrid bonding in which the insulating films are directly bonded to each other, the through-silicon vias having conductivity are directly bonded to each other, and the thermal conductors are directly bonded to each other.

In the semiconductor device 10 configured as described above, the element layer 14a of the base substrate 11 and the element layer 22a of each of the semiconductor chips 21 generate heat. As in this example, when the logic operation circuit of the base substrate 11 is formed and the semiconductor chip 21 is a memory element, the element layer 14a of the base substrate 11 generates much more heat than the element layer 22a of the semiconductor chip 21.

Although the silicon layers 14 and 22 on which the element layers 14a and 22a serving as heat sources are formed to have relatively good thermal conduction, the thermal conduction between the base substrate 11 and the chip stacked body 12 and between the semiconductor chips 21 in the chip stacked body 12 is small. This is because an insulating film made of silicon oxide (SiO₂) having low thermal conductivity is interposed between the top base substrate 11 and the chip stacked body 12, and between the stacked semiconductor chips 21 of the chip stacked body 12. Such an insulating film is an interlayer insulating film of the multi-layer wiring layers 15 and 23, a protective film, an insulating film formed on a substrate for bonding, or the like. In addition, in a thermal via or the like in the related art, an insulating film made of silicon oxide is interposed between the silicon layer and the through-silicon via, and thus the heat generated in the element layer is less likely to be transferred from the silicon layer to the through-silicon via, and the sufficient heat dissipation effect cannot be obtained.

In contrast, in the semiconductor device 10 having the above-described configuration, the insulating films 33 and 34 disposed between the thermal conductor 35 and the silicon layers 14 and 22 are made of AlN having high thermal conductivity. Therefore, the heat generated in the element layers 14a and 22a is effectively conducted from the silicon layers 14 and 22 to the thermal conductor 35 via the insulating films 33 and 34. That is, the heat is transferred well from the silicon layers 14 and 22 to the thermal conductor 35 without being significantly hindered by the insulating films 33 and 34. The heat from the thermal conductor 35 is then conducted to the heat sink 37 and dissipated. In this way, the heat dissipation property of the semiconductor device 10 is further improved, and an increase in temperature of the semiconductor device 10 is effectively prevented.

FIG. 4 illustrates a chip stacked body 12 obtained by stacking the semiconductor chips 21 after a chip heat transfer portion 31c serving as the heat transfer portion 31 is formed in each of the semiconductor chips 21 of the chip stacked body 12. In each of the semiconductor chips 21 constituting the chip stacked body 12, chip through holes 41 that penetrate the semiconductor chips 21 are formed, an insulating film 42 is formed on an inner wall surface of the chip through hole 41, and a chip thermal conductor 43 is embedded in a space surrounded by the insulating film 42 in the chip through hole 41. The chip through holes 41 are provided at the same position between the respective semiconductor chips 21, the insulating film 42 is made of the material of the insulating film 34, and the chip thermal conductor 43 is made of the material of the stacked body-side thermal conductor 35b. Thereafter, the semiconductor chips 21 are stacked and bonded to form the chip stacked body 12. Accordingly, the chip through holes 41 of the respective semiconductor chips 21 are connected and integrated into the through hole 32b, and the chip thermal conductors 43 of the respective semiconductor chips 21 are connected and integrated into the stacked body-side thermal conductor 35b. The insulating film on the inner wall surface of the chip through hole 41 in the multi-layer wiring layer 23 may be omitted.

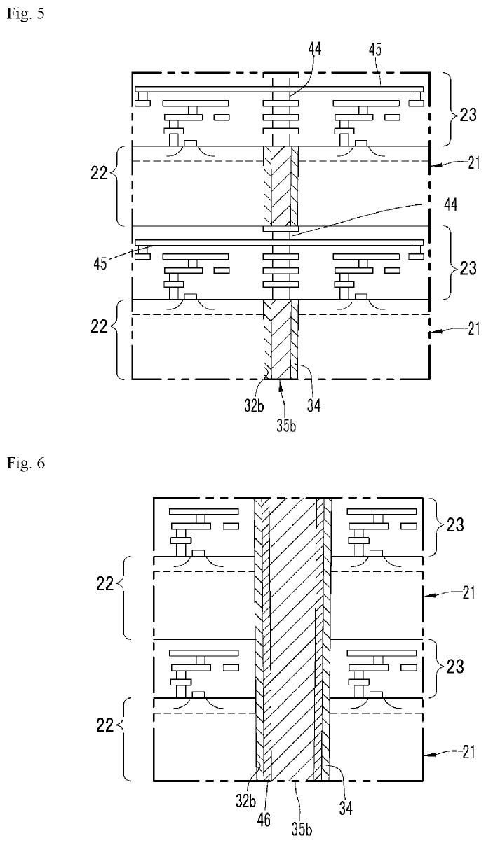

The thermal conductor 35 may be a through-silicon via electrically connected to the wiring in the wiring layer. In this case, in the chip stacked body 12, for example, as illustrated in FIG. 5, a portion of the multi-layer wiring layer 23 of the stacked body-side thermal conductor 35b is formed as a via (for example, a stack via) 44 in the multi-layer wiring layer 23 in a process of forming the multi-layer wiring layer 23, and is electrically connected to a wiring 45 of the multi-layer wiring layer 23. In this case, a via hole through which the via 44 in the multi-layer wiring layer 23 passes becomes a part of the through hole 32b. The base substrate 11 is similarly configured.

As illustrated in FIG. 6, an intermediate film 46 may be provided between the stacked body-side thermal conductor 35b and the insulating film 34. The intermediate film 46 may have one or both of a function of an adhesion layer for enhancing adhesion between the stacked body-side thermal conductor 35b and the insulating film 34 and a function of a diffusion barrier layer for preventing atoms of the stacked body-side thermal conductor 35b from diffusing into the silicon layer 22. The intermediate film 46 is preferably made of TaN, TiN, or Ni. Regarding the base substrate 11, an intermediate film may be provided between the base-side thermal conductor 35a and the insulating film 33.

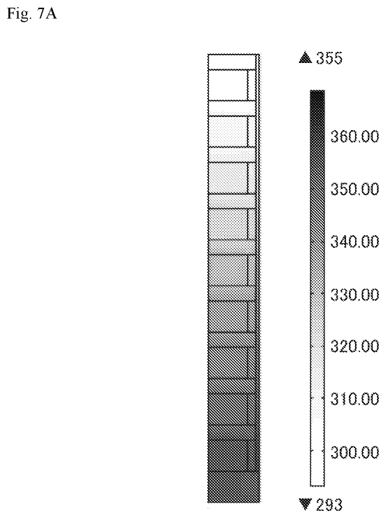

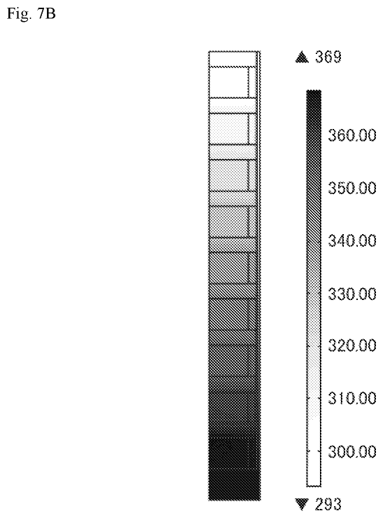

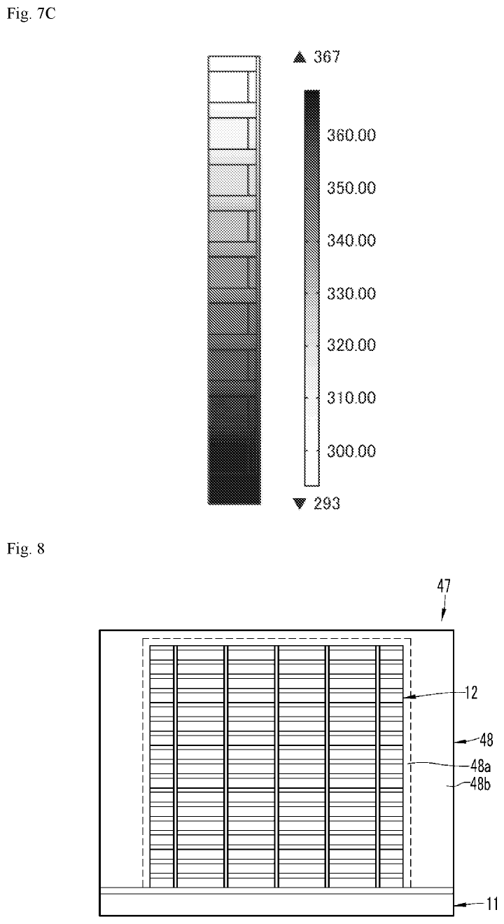

FIG. 7A illustrates a temperature distribution when simulating the heat dissipation effect in the semiconductor device 10 having the same configuration as above. In the simulation, a structure is assumed in which eight layers of memory elements are stacked as the semiconductor chips 21 on the base substrate 11 provided with a logic operation circuit that generates a large amount of heat. In FIG. 7A, a lower side corresponds to the base substrate 11. In FIGS. 7B and 7C, a lower side also corresponds to the base substrate 11.

In this simulation, a configuration in which the silicon layer 14 having a thickness of 20 μm and the multi-layer wiring layer 15 having a thickness of 10 μm are provided on a silicon substrate having a thickness of 20 μm was regarded as the base substrate 11. In addition, the chip stacked body 12 has a configuration in which eight layers of the semiconductor chips 21 each including the silicon layer 22 having a thickness of 20 μm and the multi-layer wiring layer 23 having a thickness of 10 μm are stacked. The heat sink 37 is omitted. The simulation was performed assuming that the silicon layers 14 and 22 are made of Si, and the multi-layer wiring layers 15 and 23 are made of SiO₂.

Widths of the base substrate 11 and the chip stacked body 12 are set to 30 μm, and the heat transfer portion 31 is provided at one end in a width direction. In the silicon layers 14 and 22, a region within 5 μm from the thermal conductor 35 is set as a Keep-out zone (KOZ). The thermal conductor 35 is made of Cu with a width of 5 μm, the insulating films 33 and 34 are made of AlN with a thickness of 200 nm and a thermal conductivity of 180 W/mK. The insulating films 33 and 34 are also formed on inner wall surfaces of hole portions 32 in the multi-layer wiring layers 15 and 23.

Interfaces between the silicon layers 14 and 22 and the multi-layer wiring layers 15 and 23 are heat generation regions. The logic operation circuit is formed in the base substrate 11, and a heat generation density in the heat generation region is set to 10⁷ (W/m²). Each of the semiconductor chips 21 is used as a memory element, and the heat generation density in the heat generation region is set to 10⁶ (W/m²).

In the simulation, in the heat transfer portion 31, the insulating films 33 and 34 are provided only in portions in contact with the silicon layers 14 and 22 and the multi-layer wiring layers 15 and 23, and there is no inflow and outflow of heat from end portions in the width direction. In addition, a temperature of an uppermost surface of the semiconductor device 10 is 293.15 (K). For comparison, a case in which the material of the insulating film in the heat transfer portion is SiO₂ (thermal conductivity: 1.4 W/mk) was simulated. The temperature distribution obtained by the simulation is illustrated in FIG. 7B.

The temperature of the silicon layer 14 of the base substrate 11 is 369 (K) when the insulating film is made of SiO₂, but is reduced to 355 (K) when the insulating films 33 and 34 are made of AlN. From this result, it is understood that when the insulating films 33 and 34 are made of AlN, the heat generated in the element layers 14a and 22a is more effectively transferred from the silicon layers 14 and 22 to the thermal conductor 35 via the insulating films 33 and 34, thereby dissipating the heat.

FIG. 7C illustrates a temperature distribution when simulating the heat dissipation effect in a configuration similar to that described above, in which the insulating film of the heat transfer portion of the semiconductor chip is made of SiO₂ and only the insulating film of the heat transfer portion 31 of the base substrate 11 is made of AlN. In this configuration, the temperature of the silicon layer 14 of the base substrate 11 is 367 (K). From the result and the above-described results, it is understood that it is preferable to form the insulating film of AlN (or BN), not only in the semiconductor chip of a main heat generation source but also in the semiconductor chip stacked thereon.

### Second Embodiment

In the second embodiment, a heat dissipation film made of AlN, BN or the like is provided on a surface of a semiconductor chip or a chip stacked body in order to enhance heat dissipation (heat exhaust) from the semiconductor chip or the chip stacked body. The semiconductor device of the second embodiment is the same as the semiconductor device of the first embodiment except for the following details.

As illustrated in FIG. 8, in a semiconductor device 47, a heat dissipation film 48 is provided to cover the periphery, that is, side surfaces (side wall surfaces) and the upper surface of the chip stacked body 12 serving as a chip body, and a region of the substrate surface of the base substrate 11 serving as the base semiconductor chip having a larger chip size than the semiconductor chip 21 that is not covered with the chip stacked body 12. Therefore, the chip stacked body 12 is embedded in the heat dissipation film 48. The heat dissipation film 48 is made of AlN as a film material having the electrical insulating property and high thermal conductivity. That is, the heat dissipation film 48 is an insulating film. The semiconductor device 47 illustrated in FIG. 8 is basically the same as the semiconductor device of the first embodiment except that the heat dissipation film 48 is provided and the heat sink is omitted. In order to avoid complication of the drawings, the hatching of the cross section of each part is omitted in FIG. 8. The same applies to the other drawings.

The heat dissipation film 48 in this example has a two-layer structure including an inner layer 48a formed in direct contact with the side surfaces and the upper surface of the chip stacked body 12 and the substrate surface of the base substrate 11, and an outer layer 48b formed on an outer surface of the inner layer 48a. The inner layer 48a is prepared by reducing damage to the base substrate 11 and the chip stacked body 12 by using, for example, a sputtering method performed at a low temperature (for example, 300 °C or less) at which the base substrate 11 and the chip stacked body 12 are not affected. The outer layer 48b is prepared by using an aerosol deposition method, a cold spray method, or a supersonic free jet PVD method, which has a high deposition rate. There is a concern that the aerosol deposition method, the cold spray method, or the supersonic free jet PVD method may cause damage to an object to be deposited, but by applying these methods while protecting the chip stacked body 12 and the base substrate 11 with the inner layer 48a, the heat dissipation film 48 can be formed efficiently without causing damage. The inner layer 48a may be formed to a thickness of, for example, several hundred nm. When the formation methods are different in this way, the inner layer 48a and the outer layer 48b can be distinguished by a difference in particle diameter and a difference in density. In this example, the outer layer 48b is a first insulating film (first heat dissipation film), and the inner layer 48a is a second insulating film (second heat dissipation film).

The aerosol deposition method is described in detail, for example, in the document “Byung-Dong Hahn et al., ‘Fabrication and characterization of aluminum nitride thick film coated on aluminum substrate for heat dissipation,’ Ceramics International Volume 42, Issue 16, December 2016, Pages 18141-18147”, the cold spray method is described in detail, for example, in the document “F. Eid, A. Uppal and J. Swan, ‘Cold Spray: A Disruptive Technology for Enabling Novel Packaging Thermomechanical Solutions,’ 2021 IEEE 71st Electronic Components and Technology Conference (ECTC), 2021, pp. 1109-1114”, and the supersonic free jet PVD method is described in detail, for example, in WO2017/154774.

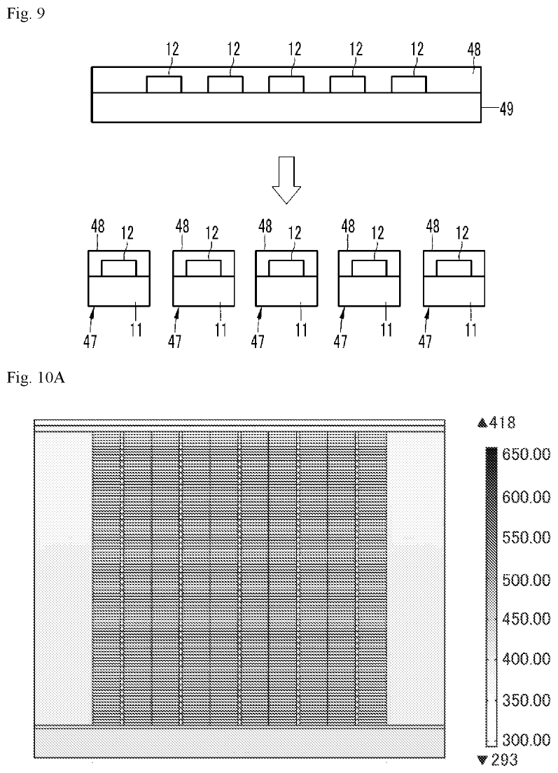

For example, as illustrated in FIG. 9, the semiconductor device 47 can be manufactured by forming the heat dissipation film 48 to cover the plurality of chip stacked bodies 12 on the wafer 49 in a state in which the plurality of chip stacked bodies 12 are bonded to a surface of the wafer 49 as CoW (Chip on Wafer) and performing dicing for each of the chip stacked bodies 12. That is, the chip stacked body 12 is provided on each of the base substrates 11 of the wafer 49 on which a plurality of base substrates 11 are provided separately. Thereafter, the heat dissipation film 48 is formed to cover the chip stacked bodies 12 together with the exposed surface of the wafer 49, and then the dicing is performed to cut the wafer 49 together with the heat dissipation film 48 into the individual base substrates 11.

In the semiconductor device 47 having the heat dissipation film 48 formed thereon as described above, the heat of the silicon layers 14 and 22 is transferred to the heat dissipation film 48 through the silicon layers 14 and 22 themselves and is dissipated from the heat dissipation film 48. That is, in the semiconductor device 47, the heat dissipation property from the periphery of the silicon layers 14 and 22 is improved.

In the above-described example, the chip stacked body 12 is a chip body, but the chip body may be one layer of semiconductor chip 21. That is, only one layer of the semiconductor chip 21 may be provided on the base substrate 11, and the heat dissipation film 48 may be formed on the side surfaces and the upper surface of the semiconductor chip 21 and on the substrate surface of the base substrate 11. In addition, in this example, the heat transfer portion is provided in the base substrate 11 and the chip stacked body 12, but the heat transfer portion may be omitted.

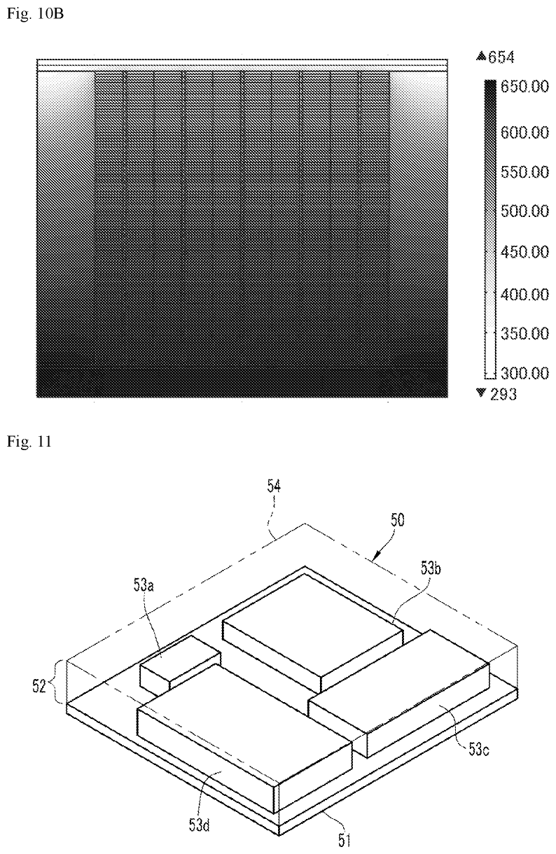

FIG. 10A illustrates a temperature distribution when the heat dissipation effect of the semiconductor device 47 configured as described above was simulated. In the simulation, a structure is assumed in which the semiconductor chips 21 serving as the memory elements are stacked on the base substrate 11 provided with a logic operation circuit that generates a large amount of heat. In the simulation, the base substrate 11 has a configuration in which the silicon layer 14 having a thickness of 10 μm and the multi-layer wiring layer 15 having a thickness 10 μm were provided on a silicon substrate having a thickness of 100 μm. In addition, the chip stacked body 12 has a configuration in which 50 layers of the semiconductor chips 21 each including the silicon layer 22 having a thickness of 10 μm and the multi-layer wiring layer 23 having a thickness of 10 μm were stacked. The simulation was performed assuming that the silicon layers 14 and 22 are made of Si, and the multi-layer wiring layers 15 and 23 are made of SiO₂. A protective film made of SiO₂ is formed on an upper surface of the heat dissipation film 48.

The thermal conductor 35 is made of Cu with a diameter of 10 μm, the insulating films 33 and 34 are made of a film material of AlN with a thickness of 200 nm. The interfaces between the silicon layers 14 and 22 and the multi-layer wiring layers 15 and 23 are heat generation regions. The logic operation circuit is formed in the base substrate 11, and a heat generation density in the heat generation region is set to 10⁶ (W/m²). Each of the semiconductor chips 21 is used as a memory element, and the heat generation density in the heat generation region is set to 10⁵ (W/m²). A temperature of the uppermost surface of the semiconductor device 10 is 293.15 (K).

For comparison, in the same configuration, a case in which the material of the heat dissipation film provided around the chip stacked body 12 is SiO₂ was simulated. The results are illustrated in FIG. 10B. A maximum temperature reached 654 (K) in the semiconductor device in which the heat dissipation film is made of SiO₂, but the maximum temperature reached 418 (K) in the semiconductor device 47, and a large temperature reduction effect was obtained.

The heat dissipation film 48 may be made of BN instead of AlN. The inner layer 48a and the outer layer 48b may be made of different film materials. That is, one of the inner layer 48a and the outer layer 48b may be made of AlN, and the other may be made of BN. In addition, the inner layer 48a may be made of SiO₂, and the outer layer 48b may be made of AlN or BN.

The semiconductor device 50 illustrated in FIG. 11 includes, for example, a base substrate 51 and a reconstruction layer 52 provided on the base substrate 51. The reconstruction layer 52 includes a plurality of semiconductor chips 53a to 53d arranged on the base substrate 51, and a heat dissipation film 54 serving as an insulating film that is formed on the base substrate 51 and in which the semiconductor chips 53a to 53d are embedded. The base substrate 51 includes, for example, a single or multiple wiring layers, and terminals connected to the semiconductor chips 53a to 53d. The semiconductor chips 53a to 53d are dies called chiplets that are divided for each function, are connected to one another via a wiring on the base substrate 51 or via a wiring formed in the heat dissipation film 54 (both not illustrated) and function as a single system.

As described above, the semiconductor chips 53a to 53d are embedded in the heat dissipation film 54. That is, the semiconductor chips 53a to 53d are arranged in the heat dissipation film 54, and the side surfaces and the upper surface thereof are covered with the heat dissipation film 54. The heat dissipation film 54 also fills trenches between the semiconductor chips 53a to 53d, and has a planarized upper surface. The heat dissipation film 54 is made of AlN or BN. Accordingly, the heat of the semiconductor chips 53a to 53d is transferred to the heat dissipation film 54 and dissipated from the heat dissipation film 54, thereby improving the heat dissipation property. In this example, each of the semiconductor chips 53a to 53d is a chip body. Of course, the chip body embedded in the heat dissipation film 54 may be a chip stacked body.

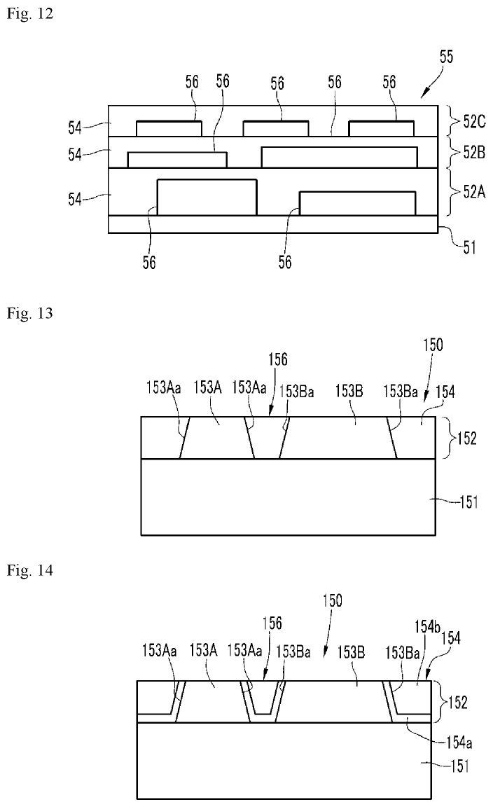

The semiconductor device 55 illustrated in FIG. 12 is provided by stacking a plurality of reconstruction layers 52A to 52C on the base substrate 51. The reconstruction layers 52A to 52C have the same configuration as the reconstruction layer 52 in the example of FIG. 11, and includes a plurality of semiconductor chips 56 serving as chip bodies and the heat dissipation film 54 in which the semiconductor chips 56 are embedded. One of the semiconductor chips 56 may be provided in the reconstruction layer. The semiconductor chips 56 provided in the reconstruction layers 52A to 52C and the combinations thereof may be the same or different. The reconstruction layers 52A to 52C and the base substrate 51 are connected to each other by a wiring (not, illustrated) extending in the stacking direction. In this example, the number of reconstruction layers is three, but may be two or four or more.

FIG. 13 illustrates an example in which the side surfaces (side wall surfaces) of the semiconductor chip are inclined surfaces. In a semiconductor device 150 illustrated in FIG. 13, a reconstruction layer 152 is provided on a base substrate 151 as in the example illustrated in FIG. 11. The reconstruction layer 152 includes a plurality of semiconductor chips 153A and 153B serving as chip bodies arranged on the base substrate 151, and a heat dissipation film 154 serving as an insulating film in which the semiconductor chips 153A and 153B are embedded. The semiconductor chip 153A and the semiconductor chip 153B are arranged with an interval therebetween.

Side surfaces 153Aa of the semiconductor chip 153A are upward inclined surfaces. That is, the side surface 153Aa is an inclined surface whose surface position approaches a center of the semiconductor chip 153A from a lower surface (surface on a base substrate 151 side) of the semiconductor chip 153A toward an upper surface (surface on a side opposite to the base substrate 151) of the semiconductor chip 153A. Therefore, the entire semiconductor chip 153A has a tapered shape in which a cross-sectional size gradually decreases toward the upper surface (away from the base substrate 151). The same applies to side surfaces 153Ba of the semiconductor chip 153B, and the side surfaces 153Ba are upward inclined surfaces.

The side surfaces 153Aa and 153Ba are, for example, inclined surfaces formed by inclining cut surfaces to be the side surfaces 153Aa and 153Ba at the time of performing dicing for cutting out the semiconductor chips 153A and 153B from the wafer. Dry etching such as plasma dicing can be preferably used as a dicing method.

The heat dissipation film 154 is made of a film material of AlN or BN. When the heat dissipation film 154 is formed, a sputtering method, an aerosol deposition method, a cold spray method, a supersonic free jet PVD method, and the like can be preferably used as described above.

A trench 156 is formed between the semiconductor chip 153A and the semiconductor chip 153B, with a part of the substrate surface of the base substrate 151 as a bottom surface thereof and the side surfaces 153Aa and 153Ba as inner wall surfaces thereof. The heat dissipation film 154 is also formed in such a trench 156. As described above, the side surfaces 153Aa and 153Ba are upward inclined surfaces, and thus an upper portion of the trench 156 is wider than a bottom surface thereof. Accordingly, even when the heat dissipation film 154 is formed by using a formation method having strong anisotropy such as a sputtering method, an aerosol deposition method, a cold spray method, and a supersonic free jet PVD method, the film material can be deposited in the trench 156 without voids. Therefore, the semiconductor device 150 having excellent heat dissipation property can be obtained. This is particularly useful when the interval between the semiconductor chips 153A and 153B is narrow.

In addition, the side surfaces 153Aa and 153Ba constituting the inner wall surfaces of the trenches 156 are inclined surfaces as compared with a case in which the side surfaces 153Aa and 153Ba stand vertically from the substrate surface of the base substrate 151, and thus the film material can be easily adhered and deposited thereon. Therefore, even in a case in which a semiconductor chip is disposed alone on the base substrate, or even in a case in which the intervals between the plurality of semiconductor chips are large, making the side surfaces of the semiconductor chips the upward inclined surfaces is useful to improve the heat dissipation property.

As illustrated in the example of FIG. 14, the heat dissipation film 154 may have a two-layer structure including the inner layer 154a and the outer layer 154b. The inner layer 154a is formed in direct contact with the side surfaces 153Aa and 153Ba of the semiconductor chips 153A and 153B and the substrate surface of the base substrate 151. The outer layer 154b is formed on an outer surface of the inner layer 154a. The details of the two-layer structure including the inner layer 154a and the outer layer 154b, the film material, and the formation method are similar to those in the example illustrated in FIG. 8.

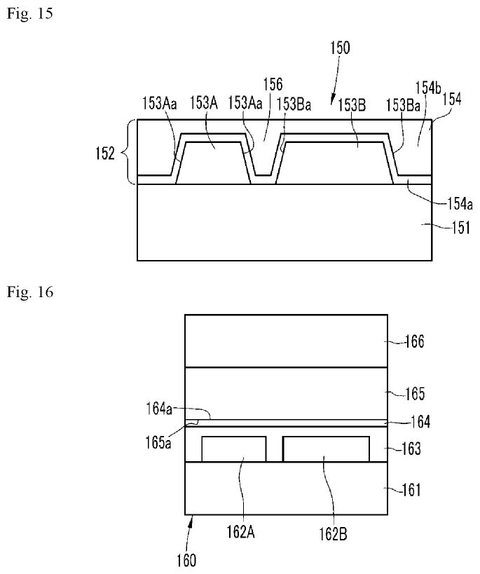

As illustrated in FIG. 15, the heat dissipation film 154 may be formed on the upper surface as well as on the side surfaces 153Aa and 153Ba of the semiconductor chips 153A and 153B, and the semiconductor chips 153A and 153B may be embedded in the heat dissipation film 154. The heat dissipation film 154 in the example of FIG. 15 has a two-layer structure including the inner layer 154a and the outer layer 154b, but may have a single-layer structure.

FIG. 16 illustrates an example in which a silicon heat spreader is attached to the heat dissipation film made of AlN. In the semiconductor device 160, chip bodies 162A and 162B are provided on a substrate surface of a base substrate 161, and the chip bodies 162A and 162B are embedded in a heat dissipation film 163 so as to cover upper surfaces thereof. The chip bodies 162A and 162B are one layer of semiconductor chip or a chip stacked body. The heat dissipation film 163 is made of AlN. A silicon heat spreader 165 is fixed to an upper surface of the heat dissipation film 163 via a bonding layer 164 formed of thin Si, and a heat sink 166 is fixed to the heat spreader 165.

In the heat spreader 165, after the heat dissipation film 163 is formed, the heat dissipation film 163 is planarized, the bonding layer 164 is formed, and bonding surfaces 164a and 165a of the bonding layer 164 and the heat spreader 165 are activated in sequence, and then the heat spreader 165 is bonded to the bonding layer 164 by bringing the bonding surface 164a and the bonding surface 165a into close contact with each other. The heat dissipation film 163 is planarized by, for example, chemical mechanical polishing (CMP). The bonding layer 164 is formed on the planarized surface of the heat dissipation film 163 by sputtering, and a surface (bonding surface 164a) is planarized by CMP. The bonding surfaces 164a and 165a can be activated by, for example, plasma activation.

When a heat dissipation film is formed by using the aerosol deposition method, it is preferable to relatively move the nozzle that sprays the aerosol and the base substrate to which the semiconductor chip is fixed, based on the layout of the semiconductor chip on the base substrate.

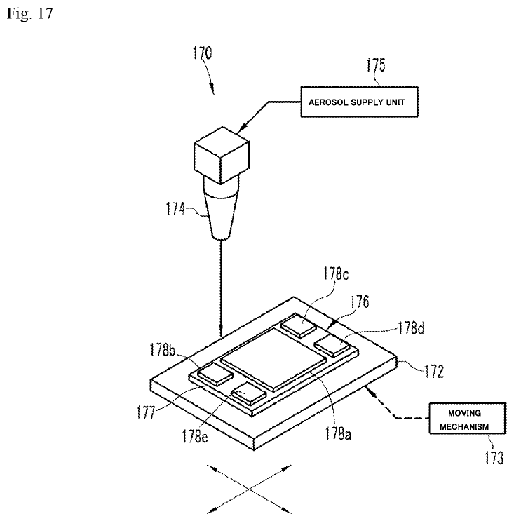

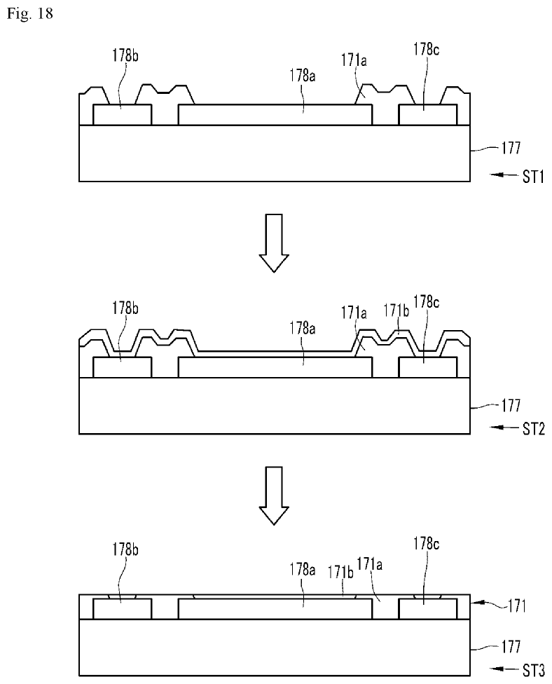

A film forming device 170, an example of which is illustrated in FIG. 17, forms a heat dissipation film 171 (see FIG. 18) by using the aerosol deposition method. The film forming device 170 includes a stage 172, a moving mechanism 173, a nozzle 174, and an aerosol supply unit 175. A semiconductor device 176 is placed on a stage surface of the stage 172. The semiconductor device 176 is provided with one layer of semiconductor chip or a plurality of chip bodies, five chip bodies 178a to 178e in this example, that are chip stacked bodies in a predetermined layout on a substrate surface of a base substrate 177.

The nozzle 174 is disposed above the stage 172 and sprays aerosol to be supplied from the aerosol supply unit 175 at a high speed toward the semiconductor device 176 (substrate surface of the base substrate 177) on the stage 172. The aerosol sprayed from the nozzle 174 is a film material, for example, raw material fine particles made of AlN fine particles and dispersed in a carrier gas. Accordingly, a film is formed on the semiconductor device 176 by kinetic energy of the raw material fine particles in the aerosol to form the heat dissipation film 171. In the case in which the chip bodies 178a to 178e are semiconductor chips, it is also preferable that the side surfaces are upward inclined surfaces as in the example illustrated in FIG. 13 and the like.

The moving mechanism 173 moves the stage 172 within a plane parallel to the substrate surface of the base substrate 177 based on the layout of the chip bodies 178a to 178e on the base substrate 177. This movement mainly involves moving the base substrate 177 on the stage 172 so that the aerosol is sprayed onto regions around the chip bodies 178a to 178e, including regions between the adjacent chip bodies. For example, the stage 172 is moved relatively quickly in a region of upper surfaces of the chip bodies 178a to 178e and moved slowly in regions other than the upper surfaces of the chip bodies 178a to 178e (regions around the chip bodies 178a to 178e or regions between the adjacent chip bodies). While keeping a movement speed of the stage 172 constant, the stage 172 may be moved so that the number of times the regions of the upper surfaces of the chip bodies 178a to 178e are scanned with the aerosol is larger than the number of times the regions of the upper surfaces of the chip bodies 178a to 178e are scanned, or the stage 172 may be moved so that the aerosol is sprayed while avoiding the regions of the upper surfaces of the chip bodies 178a to 178e.

FIG. 18 illustrates an example of a procedure in a case in which the chip bodies 178a to 178e are completely embedded in the heat dissipation film 171 and planarized using the film forming device 170. FIG. 18 illustrates a state of the film formation on a cross section taken along a cutting line in a direction in which the chip bodies 178a to 178c are arranged.

First, mainly, the semiconductor device 176 is moved with respect to the nozzle 174 by the movement of the stage 172 so that the aerosol is sprayed onto the portion between the adjacent chip bodies and the other portion around the chip bodies 178a to 178e. Then, during this movement, the aerosol is sprayed from the nozzle 174.

Accordingly, a heat dissipation film 171a is formed in the portion between the chip bodies and the other portion around the chip bodies 178a to 178e (step ST1). The heat dissipation film 171a is formed, for example, such that a height from the substrate surface of the base substrate 177 is equal to or larger than a height of each of the chip bodies 178a to 178e. In this step, the object is to form the heat dissipation film 171a in the portion between the chip bodies and in the other portion around the chip bodies 178a to 178e, but during this process, the aerosol may be sprayed onto the upper surfaces of the chip bodies 178a to 178e, or the heat dissipation film 171a may be formed on those upper surfaces.

Next, the semiconductor device 176 is moved together with the stage 172 so that the entire surface on a substrate surface side of the base substrate 177 of the semiconductor device 176 is scanned with the nozzle 174, including the upper surfaces of the chip bodies 178a to 178e. Accordingly, the aerosol is sprayed onto the entire surface of the semiconductor device 176, and an upper heat dissipation film 171b with which the chip bodies 178a to 178e and the heat dissipation film 171a are covered is formed (step ST2). After the upper heat dissipation film 171b is formed, an upper portion of the semiconductor device 178 is polished to form the planarized heat dissipation film 171 including the heat dissipation film 171a and the upper heat dissipation film 171b (step ST3). The upper heat dissipation film 171b may have a small thickness, for example, and thus can be formed in a relatively short time even if it is formed on the entire surface.

By forming the heat dissipation film 171 as described above, the film material is efficiently deposited on the portion between the chip bodies and on the other portion around the chip bodies 178a to 178e, thereby forming the heat dissipation film 171. Therefore, a time required to form the heat dissipation film 171 can be shortened, and an amount of raw material fine particles (film material) used can be reduced. The upper heat dissipation film 171b may be formed by using other formation methods. The film material of the upper heat dissipation film 171b may be the same as or different from that of the heat dissipation film 171a. Further, the inner layer of the heat dissipation film may be formed by CVD or the like, and then the heat dissipation film 171 may be formed as an outer layer as described above.

It is also preferable that the heat dissipation film in each of the above-described examples is made of Al₂O₃ or Si₃N₄ having good insulating property and thermal conductivity. In addition, both good mechanical strength and thermal conductivity can be achieved, and thus it is also preferable to form the heat dissipation film of a composite material obtained by mixing AlN and Si₃N₄. Any film material of Al₂O₃, Si₃N₄, or a composite material of AlN and Si₃N₄ can preferably form a heat dissipation film by, for example, using the aerosol deposition method. The inner layer and the outer layer can be made of a film material of AlN, BN, Al₂O₃, Si₃N₄, or a composite material of AlN and Si₃N₄. The inner layer and the outer layer may be made of different materials selected from these film materials. Further, the inner layer may be made of SiO₂, and the outer layer may be made of a material selected from the above-described film materials.

When the heat dissipation film is formed of the composite material by using the aerosol deposition method, the raw material fine particles obtained by mixing fine particles of AlN and Si₃N₄ may be dispersed in a carrier gas to form aerosol, and the aerosol may be sprayed onto the chip stacked body, the semiconductor chip, the base substrate, and the like at a high speed. Accordingly, a composite film in which AlN and Si₃N₄ are randomly deposited is formed as a heat dissipation film. A ratio of the fine particles of AlN and Si₃N₄ in the raw material fine particles is preferably 50%.

### Third Embodiment

In the third embodiment, the wiring layer insulating film is made of AlN or BN. The semiconductor device of the third embodiment is the same as the semiconductor device of the first embodiment except for the following details. In the third embodiment, a case in which AlN is used as the film material of the interlayer insulating film having the electrical insulating property and thermal conductivity will be described, but BN may be used as the film material instead of AlN. Furthermore, the wiring portion is made of Cu, and a material of the wiring portion is not limited thereto.

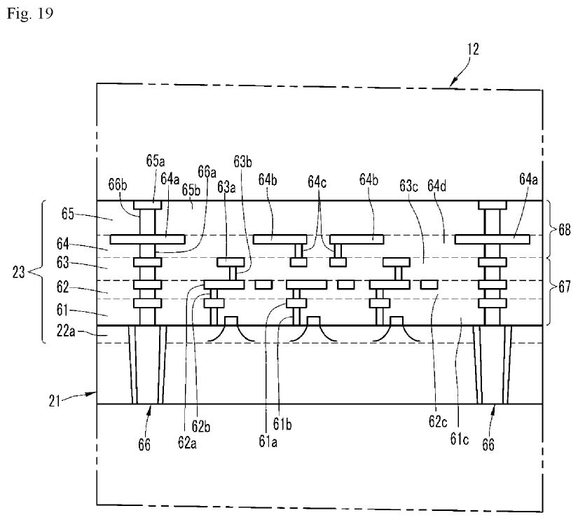

In FIG. 19, the multi-layer wiring layer 23 serving as a wiring structure formed on each of the semiconductor chips 21 of the chip stacked body 12 in this example has a five-layer structure including wiring layers 61 to 65 from an element layer 22a side. The multi-layer wiring layer 23 is roughly divided into a lower-layer wiring region 67 including the wiring layers 61 to 63 on the element layer 22a side and an upper-layer wiring region 68 including the wiring layers 64 and 65 on an upper portion. The multi-layer wiring layer 23 having a five-layer structure is described as an example, but the number of the wiring layers is not limited thereto. The multi-layer wiring layer 23 formed on each of the semiconductor chips 21 of the chip stacked body 12 is described in this example, but a multi-layer wiring layer may be formed on one layer of semiconductor chip 21. In order to avoid complication of the drawings, the hatching of the cross section of each part is omitted in FIG. 19. The same applies to the other drawings.

The lower-layer wiring region 67 is a wiring region that is responsible for a relatively short-distance electrical connection called a local wiring (Metal 1) that connects local transistors, an intermediate wiring that connects cells, or the like, and has a small wiring width and a small wiring interval. The lowermost wiring layer 61 carries a local wiring. The wiring layer 61 includes wirings 61a serving as wiring portions, contacts 61b that connect the transistors to the wirings 61a, and an interlayer insulating film 61c, and has a structure in which the wirings 61a and the contacts 61b are embedded in the interlayer insulating film 61c. That is, the wirings 61a and the contacts 61b are formed in the interlayer insulating film 61c.

Wiring layers 62 and 63 above the wiring layer 61 are wiring regions that carry, for example, the intermediate wiring. In the wiring layer 62, wirings 62a each constituting a wiring portion and vias 62b connecting the wirings 62a to the lower-layer wirings 61a are formed in an interlayer insulating film 62c. The same applies to the wiring layer 63, and vias 63b and wirings 63a constituting a wiring portion are formed in an interlayer insulating film 63c.

The upper-layer wiring region 68 is a wiring region called a global wiring that is responsible for long-distance electrical connections that supply signals or power to the entire chip. In this example, a power delivery network (PDN) for supplying power to the second wiring layer 64 in a second layer from the top is formed. This wiring layer 64 serving as a power supply wiring layer includes wirings 64a and 64b serving as power supply wirings, vias 64c that connect the wirings 64a and 64b to a lower-layer wiring, and an interlayer insulating film 64d, and the wirings 64a and 64b, the vias 64c, and vias 66a of through-silicon vias 66 that constitute a wiring portion are formed in the interlayer insulating film 64d. For example, the wiring 64a is a supply wiring that supplies a power supply voltage, and the wiring 64b is a ground wiring. A width of the wiring in the multi-layer wiring layer 23 is increased toward the upper-layer wiring layer, similar to that of a multi-layer wiring layer in the related art. Therefore, the wirings 64a and 64b in the wiring layer 64 are wider than those in the wiring layers 61 to 63.

The uppermost wiring layer 65 includes pads 65a that are connected to the upper-layer semiconductor chip 21 and an interlayer insulating film 65b, and the pads 65a are formed in the interlayer insulating film 65b such that upper surfaces thereof are exposed to an upper surface of the interlayer insulating film 65b.

A portion of the through-silicon via 66 in the multi-layer wiring layer 23 is formed in a stacked via structure, and a part of the stacked via structure of each of the wiring layers 61 to 65 is formed in the interlayer insulating film. In addition, in this example, the pads 65a are provided at upper end portions of the stacked via structure. In the wiring layer 65, the pads 65a and the vias 66b of the through-silicon vias 66 provided in the interlayer insulating film 65b constitute a wiring portion.

Among the interlayer insulating films 61c to 63c, 64d, and 65b serving as wiring layer insulating films, the interlayer insulating films 61c to 63c in the lower-layer wiring region 67 are made of SiO₂, and the interlayer insulating films 64d and 65b in the upper-layer wiring region 68 are made of AlN. That is, the wiring layer 64 including the wirings 64a and 64b constituting a power delivery network and the interlayer insulating films 64d and 65b of the wiring layer 65 above the wiring layer 64 are made of AlN having the electrical insulating property and high thermal conductivity. The interlayer insulating films 64d and 65b can be formed by, for example, sputtering.

With the above configuration, the heat generated in the element layer 22a or the Joule heat generated in the multi-layer wiring layer 23 is effectively diffused and dissipated via the interlayer insulating films 64d and 65b. The heat transmitted to the interlayer insulating films 64d and 65b is dissipated to the outside from peripheral portions of the interlayer insulating films 64d and 65b, is transmitted to the silicon layer 22 of the upper-layer semiconductor chip 21 and dissipated from the silicon layer 22, or is transmitted to the through-silicon vias 66 and dissipated. Accordingly, the heat dissipation properties of the semiconductor chip 21 and the chip stacked body 12 are improved.

A thin film-shaped protective layer made of SiO₂ having low thermal conductivity may be formed on the upper surface of the interlayer insulating film 65b. Even in such a case, the interlayer insulating film 65b having high thermal conductivity is bonded to the silicon layer 22 of the upper-layer semiconductor chip 21 in a relatively large area via a thin protective layer in a wide area, and thus the heat can be effectively transferred to the silicon layer 22. Therefore, the heat dissipation property is improved even in the chip stacked body 12 having such a configuration.

Only the uppermost interlayer insulating film 65b may be made of AlN, and the interlayer insulating film 64d may be made of SiO₂. In this way, by forming at least one interlayer insulating film (in this example, the interlayer insulating film 65b) of AlN having the thermal conductivity, the heat dissipation property is improved as described above.

All of the interlayer insulating films 61c to 63c, 64d, and 65b of the multi-layer wiring layer 23 can be made of AlN having high thermal conductivity. On the other hand, AlN has higher dielectric constant than SiO₂, and thus it is preferable to use AlN to form the interlayer insulating film for the upper wiring layer in the multi-layer wiring layer 23, which has a large wiring width and is less likely to cause wiring delay as in the above-described example.

In addition, in order to reduce the influence of the high dielectric constant of the interlayer insulating film made of AlN, it is preferable to provide a low dielectric constant insulating film made of a low dielectric constant material having a lower dielectric constant than AlN, for example, SiO₂, between the interlayer insulating film and the wiring portion.

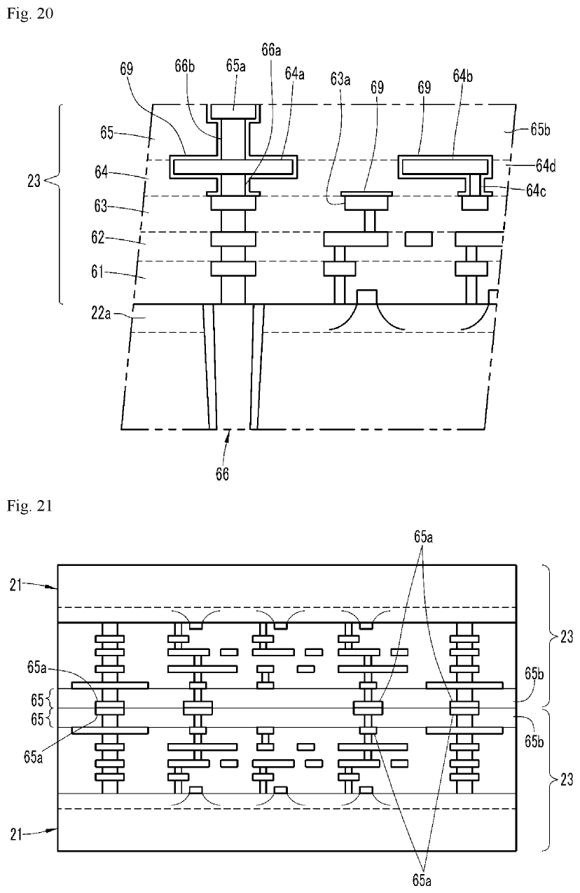

In the example illustrated in FIG. 20, a low dielectric constant insulating film 69 made of, for example, SiO₂ having a lower dielectric constant than the interlayer insulating films 64d and 65b is provided between the interlayer insulating films 64d and 65b made of AlN and the wiring portions (wirings 64a and 64b, vias 64c, pads 65a, and vias 66a and 66b) in the wiring layers 64 and 65. In addition, for the wiring 63a in the wiring layer 63 in contact with the wiring layer 64 in which the interlayer insulating film 64d is made of AlN, the low dielectric constant insulating film 69 is provided between the wiring 63a and the interlayer insulating film 64d. The low dielectric constant insulating film 69 is uniformly formed with a thickness of, for example, about 200 nm on surfaces of the wirings 63a, 64a, and 64b, the vias 64c, 66a, and 66b, and the pads 65a, which are boundaries with the interlayer insulating film. Accordingly, a parasitic capacitance of the wiring portion is reduced, and the influence of signal delay or the like is reduced.

When the film material of the interlayer insulating film is BN, the low dielectric constant insulating film 69 is made of a low dielectric constant material having a lower dielectric constant than BN. In addition, similar to the first embodiment, it is also preferable that the insulating film in the through hole of the silicon layer 22 through which the through-silicon via 66 passes is made of AlN or BN.

FIG. 21 illustrates an example in which the pair of semiconductor chips 21 configured as described above are hybrid-bonded to each other. The pair of semiconductor chips 21 bond the surfaces of the uppermost wiring layer 65 of the multi-layer wiring layer 23. This bonding is a hybrid bonding in which the interlayer insulating films 65b and the pads 65a of the pair of semiconductor chips 21 are directly bonded, respectively. The upper surface of the interlayer insulating film 65b made of AlN and the pads 65a made of Cu of each of the semiconductor chips 21 are planarized to be flush with each other, and the upper surfaces of the interlayer insulating film 65b and the pads 65a are activated by, for example, Ar (argon) plasma treatment under vacuum. Thereafter, the interlayer insulating films 65b are bonded to each other, and the pads 65a are bonded to each other.

In this example, one of the pair of semiconductor chips 21 is a first semiconductor substrate, and the other is a second semiconductor substrate. In addition, one of the interlayer insulating films 65b is a first bonding insulating film, and the other of the interlayer insulating films 65b is a second bonding insulating film. Further, one pad 65a of the pair of semiconductor chips 21 is a first electrode pad, and the other pad 65a is a second electrode pad. The bonding of the films made of AlN is described in, for example, the literature “Shuyu Bao et al. ‘AlN—AlN Wafer Bonding and Its Thermal Characteristics,’ ECS Transactions, 64 (5), 141-148 (2014)”.

An insulating film used for bonding is generally a TEOS oxide film or a SiC film in the related art, but an insulating film made of such a material has low thermal conductivity and low heat dissipation property. However, in this example, the hybrid bonding is performed using the interlayer insulating film 65b made of AlN, and thus the chips can be bonded to each other with a configuration in which the heat dissipation property is improved. The bonding is chip bonding between the semiconductor chips 21, and may be wafer bonding between the wafers. In addition, the interlayer insulating film 65b and the pads 65a of the multi-layer wiring layer 23 are bonded to each other, but the present invention can be used to bond interlayer insulating films and pads of various wiring layers.

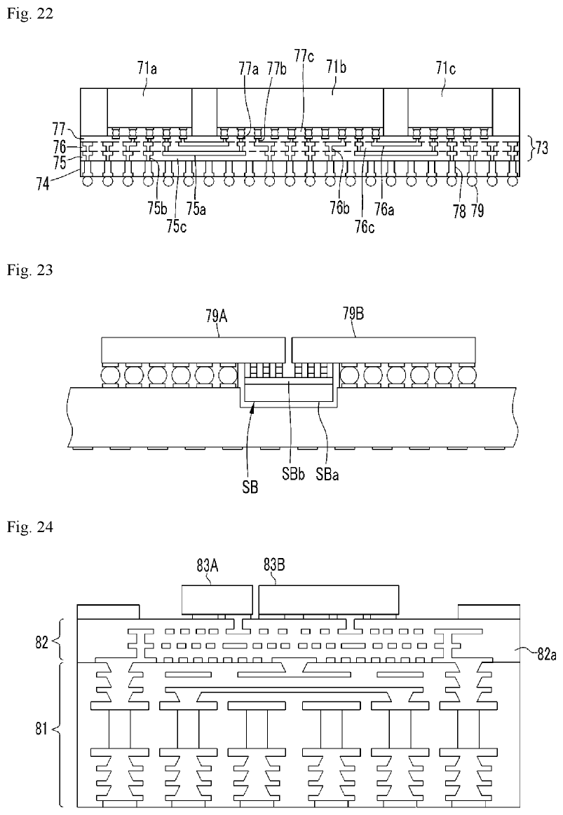

The above describes an example in which the interlayer insulating film of the multi-layer wiring layer formed in the semiconductor chip is made of AlN, but as illustrated in FIG. 22, an interlayer insulating film of an interposer 73 implemented as a multi-layer wiring layer that connects plurality of semiconductor chips 71a to 71c may also be made of AlN. The interposer 73 is implemented as a wiring structure on an upper surface of a package substrate 74 serving as a base substrate.

The interposer 73 in this example has a three-layer structure including wiring layers 75 to 77. In the wiring layer 75, wirings 75a and vias 75b are formed in an interlayer insulating film 75c. Similarly, in the wiring layer 76, wirings 76a and vias 76b are formed in an interlayer insulating film 76c. In the wiring layer 77, pads 77a and vias 77b are formed in an interlayer insulating film 77c, and an upper surface of the pad 77a is exposed on an upper surface of the interposer 73. Bumps on lower surfaces of the semiconductor chips 71a to 71c are connected to the pads 77a, a part of the semiconductor chips 71a to 71c are connected to each other through the wiring 75a and the wiring 76a, and other part of the semiconductor chips 71a to 71c are connected to a bump 79 on a lower surface of the package substrate 74 through a through-silicon via 78 that penetrates the package substrate 74.

In the wiring layers 75 to 77, the interlayer insulating films 75c to 77c are made of AlN. In the case of the interposer 73, each of the wiring portions is provided as a signal wiring used for transmitting and receiving signals between the semiconductor chips 71a to 71c. In the case of such a signal wiring, in order to improve the signal delay caused by the high dielectric constant of the interlayer insulating films 75c to 77c, it is preferable to provide a low dielectric constant insulating film between the interlayer insulating films 75c to 77c made of AlN and the wiring portions in the wiring layers 75 to 77 as in the example of FIG. 21.

According to the above-described configuration, the Joule heat generated in the wiring layers 75 to 77 is effectively diffused and dissipated via the interlayer insulating films 75c to 77c.

The interposer 73 may be a silicon interposer or an organic interposer using an interposer substrate made of an organic material such as polyimide.

An interlayer insulating film of a multi-layer wiring layer of a silicon bridge that forms a fine and high-density wiring and interconnects the semiconductor chips can also be made of AlN. As illustrated in an example in FIG. 23, a silicon bridge SB is formed with a multi-layer wiring layer SBb serving as a wiring structure on a surface of a silicon die SBa, and electrically connects a semiconductor chip 79A and a semiconductor chip 79B through the multi-layer wiring layer SBb. The semiconductor chip 79A and the semiconductor chip 79B are electrically connected to the multi-layer wiring layer SBb via, for example, C4 bumps or the like. A basic configuration of the multi-layer wiring layer SBb is the same as that of the multi-layer wiring layer provided in the interposer or the semiconductor chip, and thus the illustration and detailed description thereof are omitted. The interlayer insulating film of the multi-layer wiring layer SBb is made of AlN, and thus the Joule heat generated within the multi-layer wiring layer SBb is effectively diffused and dissipated.

Furthermore, as illustrated in FIG. 24, an interlayer insulating film 82a of a thin film layer 82 serving as a wiring structure formed as an interposer on a build-up substrate 81 is made of AlN, whereby the heat dissipation effect of the Joule heat generated in the thin film layer 82 and the heat generated in semiconductor chips 83A and 83B electrically connected to the thin film layer 82 can be enhanced.

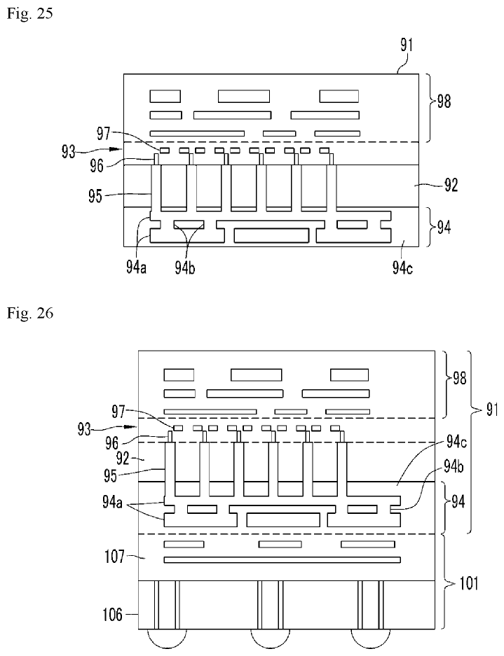

FIG. 25 illustrates an example of a structure called a back-side power delivery network (PDN), in which a power delivery network is provided on a back surface side of a semiconductor chip 91. In this example, a power supply wiring layer 94 is provided on a surface of a silicon substrate (semiconductor substrate) 92 on a side opposite to an element layer 93. The power supply wiring layer 94 includes wirings 94a and vias 94b serving as a wiring portion, and a wiring layer insulating film 94c, and has a structure in which the wirings 94a serving as power supply wirings and the vias 94b are formed in the wiring layer insulating film 94c. In this example, the wiring 94a is electrically connected to a gate all-around transistor 97 in the element layer 93 by a buried power rail (BPR) 96 and a nano-through-silicon via (nano-TSV) 95 that penetrates the silicon substrate 92. A multi-layer wiring layer 98 is formed above the element layer 93. As described above, the multi-layer wiring layer 98 does not include a power supply wiring layer since the power supply wiring layer 94 is provided separately from the multi-layer wiring layer 98. In this example, the power supply wiring layer 94 is a wiring structure and is itself a power supply wiring layer.

The wiring layer insulating film 94c is made of AlN. Accordingly, the heat generated in the element layer 93 of the semiconductor chip 91 is transferred to the wiring layer insulating film 94c through the BPR 96 and the micro-through-silicon via 95, and is effectively dissipated.

When the silicon substrate 92 becomes thin, the heat dissipation property in an in-plane direction thereof decreases, but the wiring layer insulating film 94c is made of AlN as described above, and thus the heat dissipation property can be improved. In addition, the wiring 94a of the power supply wiring layer 94 is of a power delivery network and has a wide width, and thus is less likely to be affected by the high dielectric constant of the wiring layer insulating film 94c.

In the example illustrated in FIG. 26, the power supply wiring layer 94 is provided on an interposer 101 side in a stacked structure in which the semiconductor chip 91 is bonded onto an interposer 101 by, for example, direct bonding. In the interposer 101, a multi-layer wiring layer 107 is formed on an interposer substrate 106, and the power supply wiring layer 94 is further formed on the multi-layer wiring layer 107. In this way, the heat generated in the element layer 93 of the semiconductor chip 91 is effectively dissipated by the wiring layer insulating film 94c of the power supply wiring layer 94, which is made of AlN. In this example, the power supply wiring layer 94, or the power supply wiring layer 94 and the multi-layer wiring layer 107 constitute the wiring structure.

When the interposer 101 is an organic interposer, that is, when the interposer substrate 106 is made of an organic material, the wiring layer insulating film 94c can be made of AlN at a low temperature by, for example, using the aerosol deposition method.

In each of the examples of FIGS. 23 to 26, it is preferable to provide a low dielectric constant insulating film between the interlayer insulating film or the wiring layer insulating film made of AlN or BN and the wiring portion. In particular, in the case of the wiring portion used for transmitting and receiving signals, it is useful to provide the low dielectric constant insulating film in order to reduce the signal delay.

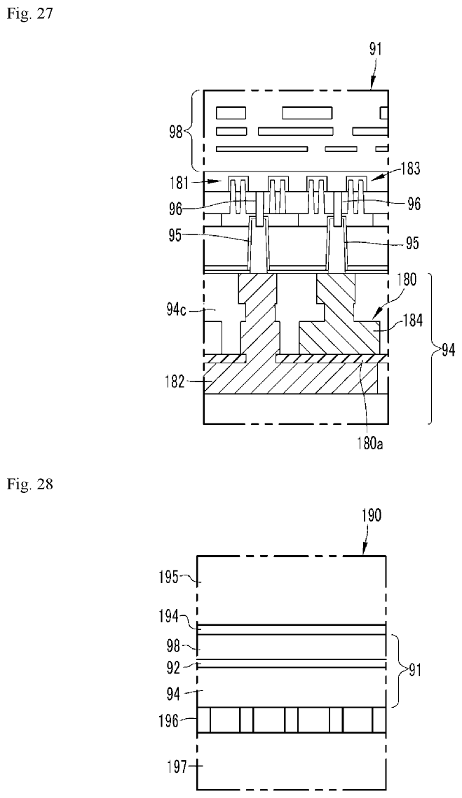

When a capacitor (MIM capacitor) 180 having a metal-insulator-metal (MIM) structure is provided in the power supply wiring layer 94 as in the example illustrated in FIG. 27, it is preferable that a dielectric layer (insulating layer) 180a is made of AlN together with the wiring layer insulating film 94c of the power supply wiring layer 94. The AlN has a large dielectric constant, and thus a large static capacitance can be implemented with a small area. In the example of FIG. 27, the dielectric layer 180a made of AlN is provided between a VDD wiring (supply wiring) 182 connected to a p-type field effect transistor 181 in the element layer 93 by the nano-through-silicon via 95 and the BPR 96 and a ground wiring 184 connected to an n-type field effect transistor 183. Accordingly, the VDD wiring 182 and the ground wiring 184, which are a pair of power supply wirings, serve as electrodes, and the VDD wiring 182 and the ground wiring 184 are disposed to face each other with the dielectric layer 180a sandwiched therebetween, thereby forming the capacitor 180. The capacitor 180 compensates for the voltage drop by the charge accumulated therein, and prevents a voltage fluctuation due to a load. In FIG. 27, only cross sections of the VDD wiring 182, the ground wiring 184, and the dielectric layer 180a are hatched, and the hatching of other cross sections is omitted.

In a semiconductor device 190 illustrated in FIG. 28, a stacked body which the power supply wiring layer 94 constituting the semiconductor chip 91, the silicon substrate (semiconductor substrate) 92 including the element layer and the silicon layer, the multi-layer wiring layer 98 in which the interlayer insulating film is made of SiO₂, a bonding layer 194, and a Si carrier 195 are sequentially stacked is provided on a package substrate 197 via a C4 bump/UF (underfill) layer 196 provided on a lower surface of the power supply wiring layer 94. The Si carrier 195 formed of silicon functions as a heat spreader while supporting the silicon substrate 92 whose thickness is thinner (for example, about 300 nm) by the rigidity thereof, and is directly bonded to the bonding layer 194 made of AlN and provided on the multi-layer wiring layer 98. The bonding layer 194 is made of AlN, and thus it is possible to enhance the heat dissipation effect of the heat generation source that is the silicon substrate 92 on which the element layer is formed. In addition, it is also useful to form the wiring layer insulating film of the power supply wiring layer 94 provided on a back surface side of the semiconductor substrate (semiconductor chip) as the back-side PDN by using AlN in order to enhance the heat dissipation effect.

The bonding layer 194 made of AlN and the Si carrier 195 made of silicon are bonded to each other by using, for example, the same method as in the example of FIG. 16. Therefore, the Si carrier 195 is provided on an upper surface of the bonding layer 194 via a silicon bonding layer.

A simulation was performed using the semiconductor device 190 having the layered structure illustrated in FIG. 28 as a model, and the heat dissipation effect was verified. In this simulation, thicknesses (lengths in a vertical direction (up-down direction in FIG. 28) ) of the power supply wiring layer 94, the silicon substrate 92, the multi-layer wiring layer 98, the bonding layer 194, the Si carrier 195, the C4 bump/UF layer 196, and the package substrate 197 are 4 μm, 0.3 μm, 2.5 μm, 1.5 μm, 300 μm, 30 μm, and 700 μm, respectively. In addition, a width (length in a horizontal direction (left-right direction in FIG. 28) ) of the semiconductor device 190 was set to 55 μm.

At a boundary between the silicon substrate 92 and the multi-layer wiring layer 98, a heat generation region having a width of 20 μm generates heat at a center in a width direction. The heat generation region generates heat at 1 MW/m². The thermal conductivities of the silicon substrate 92 and the Si carrier 195 was that of silicon, and the thermal conductivity of the multi-layer wiring layer 98 was 4 W/m·K. The thermal conductivity of the C4 bump/UF layer 196 was 4.023 W/m·K in the vertical direction and 0.28 W/m·K in the horizontal direction, and the thermal conductivity of the package substrate 197 was 0.3 W/m·K.

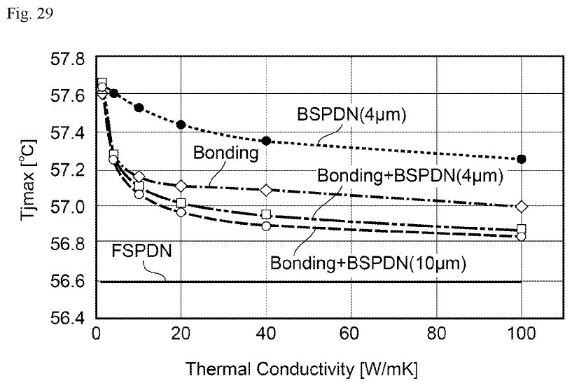

In the simulation, assuming that the power supply wiring layer 94 and the bonding layer 194 are made of AlN, thermal conductivities κ of one or both of the power supply wiring layer 94 and the bonding layer 194 are set to 1.5 W/m·K, 10 W/m·K, 20 W/m·K, 40 W/m·K, and 100 W/m·K, and a peak temperature (Tjmax) of the semiconductor device 190 for each of the thermal conductivities κ is examined. The result of this simulation is illustrated in FIG. 29. When the thermal conductivities of the power supply wiring layer 94 and the bonding layer 194 were not changed, the thermal conductivity was set to that of SiO₂ (κ=1.5 W/m·K).

In FIG. 29, “BSPDN (4 μm)” indicates a change in peak temperature when only the thermal conductivity κ of the power supply wiring layer 94 was changed. In addition, “Bonding” indicates a change in peak temperature when only the thermal conductivity κ of the bonding layer 194 was changed. Further, “Bonding+BSPDN (4 μm)” indicates a case in which the thermal conductivities κ of both the power supply wiring layer 94 and the bonding layer 194 were changed to the same value. In addition, a simulation was also performed when the thickness of the power supply wiring layer 94 was set to 10 μm and the thermal conductivities κ of both the power supply wiring layer 94 and the bonding layer 194 were changed to the same value, and the result is illustrated as “Bonding+BSPDN (10 μm)” in FIG. 29.

Furthermore, a peak temperature of a semiconductor device using a front-side PDN (FSPDN) silicon substrate in the related art in which a power delivery network is provided on an element layer side (hereinafter, referred to as an FSPDN type semiconductor device) is illustrated as “FSPDN” in FIG. 29. The semiconductor device using the front-side PDN is an example in which the insulating film of the multi-layer wiring layer including the power delivery network is made of SiO₂, but the silicon substrate is considerably thick and has high heat dissipation property as compared with the semiconductor device using the back-side PDN. The high heat dissipation property was obtained by a thick silicon substrate, and thus the FSPDN type semiconductor device was simulated as a structure in which a silicon substrate provided with a multi-layer wiring layer including a power delivery network on an element layer side was provided on the package substrate 197 via the C4 bump/UF layer 196. In the FSPDN type semiconductor device, the bonding layer 194 and the Si carrier 195 are not provided.

As can be seen from FIG. 29, it can be seen that forming one or both of the power supply wiring layer 94 and the bonding layer 194 by using AlN to improve the thermal conductivity is effective in increasing the heat dissipation effect and lowering the peak temperature. It can be seen that if the power supply wiring layer 94 and the bonding layer 194 are both formed to have the thermal conductivity K of 40 W/m·K, the peak temperature can be lowered by approximately 0.8°. In addition, in this case, it can be seen that the temperature is slightly increased (about 0.3°) with respect to the FSPDN type semiconductor device.

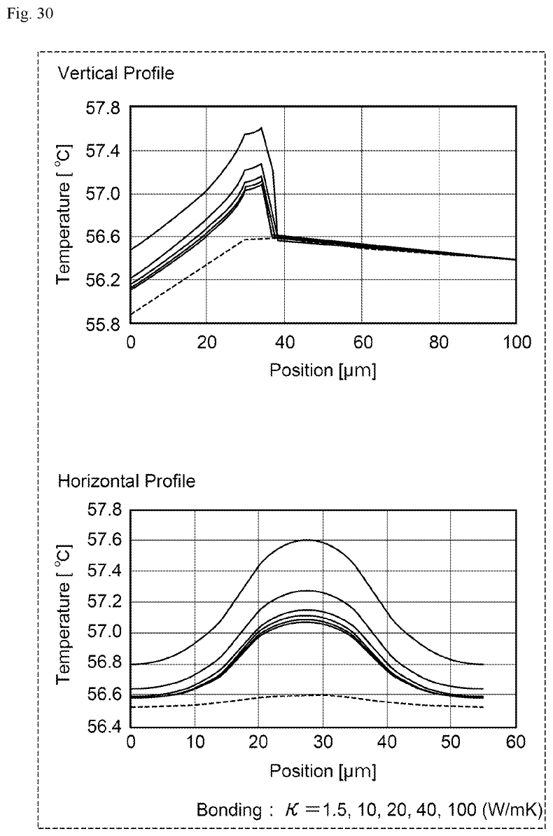

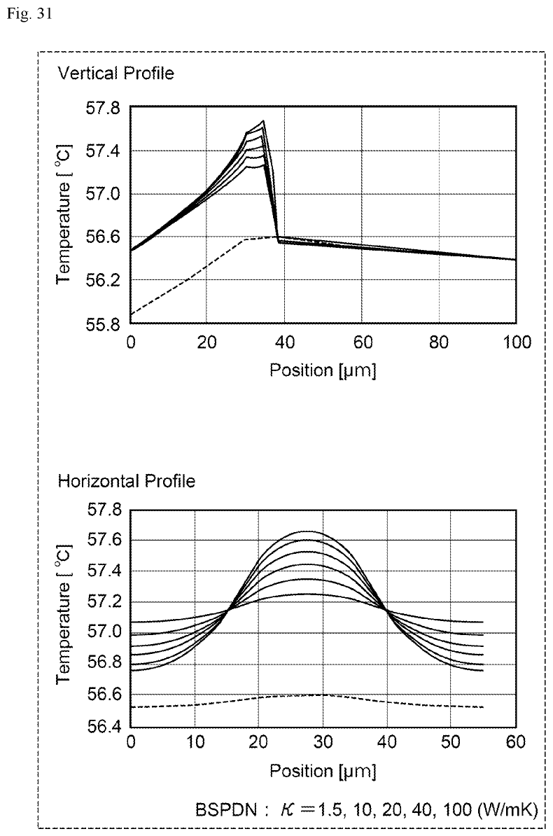

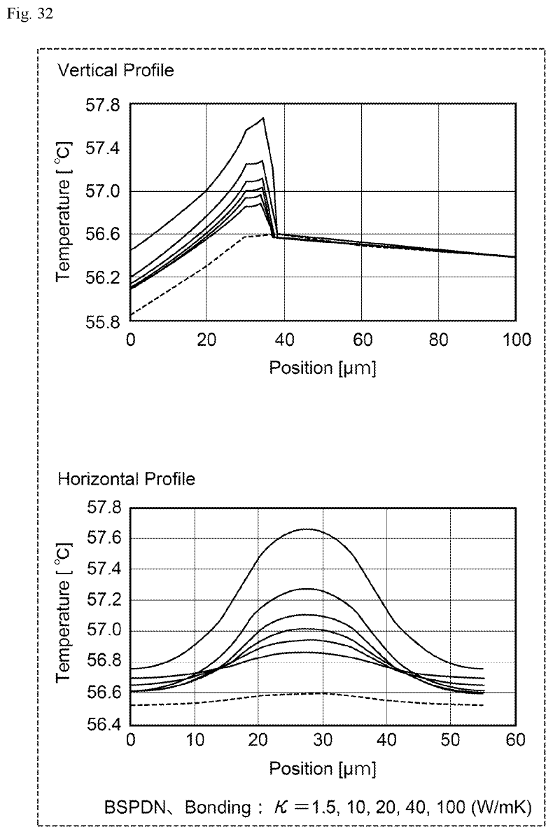

FIGS. 30 to 32 illustrate the temperature distributions of the peak temperatures in the vertical direction and the horizontal direction depending on the differences in the thermal conductivities κ (=1.5 W/m·K, 10 W/m·K, 20 W/m·K, 40 W/m·K, and 100 W/m·K) in the cases of “bonding”, “BSPDN (4 μm)”, “bonding+BSPDN (4 μm)”, and “bonding+BSPDN (10 μm)” in FIG. 29. In addition, in FIGS. 30 to 32, the case of the FSPDN type semiconductor device is illustrated by broken lines.

FIGS. 30 to 32 are graphs in which the thermal conductivity κ is 1.5 W/m·K, 10 W/m·K, 20 W/m·K, 40 W/m·K, and 100 W/m·K in order from the highest peak temperature. In addition, in the vertical direction, an interface between the package substrate 197 and the C4 bump/UF layer 196 is set as a starting point (0 μm), and in the horizontal direction, the temperature distributions are illustrated starting from an end portion of the region used in the simulation. It can be seen that when the bonding layer 194 is made of SiO₂ (κ=1.5 W/m·K), the bonding layer 194 has a large thermal resistance, and the thin silicon substrate 92 reduces the thermal diffusion. However, it can be seen that the thermal conductivity of the bonding layer 194 has an effect of reducing an interface thermal resistance and decreasing the peak temperature. Further, it can be seen that the thermal diffusion in the horizontal direction in the silicon layer 192 can be improved by increasing the thermal conductivity of the power supply wiring layer 191, thereby preventing the temperature from locally increasing.

In each of the embodiments, the film made of the film material of AlN, BN, Al₂O₃, Si₃N₄, or the composite material of AlN and Si₃N₄ (insulating film in the first embodiment, the heat dissipation film in the second embodiment, and the interlayer insulating film and the wiring layer insulating film in the third embodiment) may contain some substances other than the film materials as long as the film can ensure the electrical insulating property and higher thermal conductivity than SiO₂.

### REFERENCE SIGN LIST

10, 47, 50, 55, 150, 160, 176, 178, 190 semiconductor device
11, 51, 151, 161, 177 base substrate
12 chip stacked body
14, 22, 192 silicon layer
15, 23, 98, 107, SBb multi-layer wiring layer
21, 53a to 53d, 56, 71a to 73a, 91, 153A, 153B semiconductor chip
32a hole
32b through hole
33, 34 insulating film
35 thermal conductor
35a base-side thermal conductor
35b stacked body-side thermal conductor
37 heat sink
41 chip through hole
43 chip thermal conductor
46 intermediate film
48, 54, 154, 162, 163, 171 heat dissipation film
48a, 154a inner layer
48b, 154b outer layer
52, 52A to 52C reconstruction layer
61 to 65, 75 to 77 wiring layer
61a to 63a, 64a, 64b, 75a, 76a, 94a wiring
61c to 63c, 64d, 65b, 75c to 77c interlayer insulating film
73, 101 interposer
81 build-up substrate
82 thin film layer
94, 191 power supply wiring layer
94c wiring layer insulating film
162A, 162B, 178a to 178e chip body
164, 194 bonding layer
SB silicon bridge

1-29. (canceled)

30. A wiring structure comprising:
one or more wiring layers provided on a base substrate and disposed between the base substrate and a semiconductor chip, or formed on the semiconductor chip, wherein
a wiring in the wiring layers is electrically connected to an element of the semiconductor chip, and
the wiring structure comprises one or more of the wiring layers in which a wiring portion including the wiring is formed in a wiring layer insulating film made of AlN or BN.

31. The wiring structure according to claim 30, wherein
the wiring structure is a multi-layer wiring layer in which a plurality of the wiring layers are formed on the semiconductor chip.

32. The wiring structure according to claim 30, wherein
the wiring structure includes a plurality of the wiring layers, wherein
the plurality of wiring layers includes a power supply wiring layer in which a power supply wiring is provided as one wiring layer, and
the wiring layer insulating film in one or both of the power supply wiring layer and a wiring layer above the power supply wiring layer is made of AlN or BN.

33. The wiring structure according to claim 30, wherein
a plurality of the semiconductor chips are mounted, and
a signal wiring that electrically connects the plurality of semiconductor chips is provided as the wiring portion in an interposer.

34. The wiring structure according to claim 30, wherein
the wiring layer is formed on a silicon substrate, and
a signal wiring that electrically connects a plurality of the semiconductor chips is provided as the wiring portion in a silicon bridge.

35. The wiring structure according to claim 30, wherein
the wiring layer is formed on a build-up substrate.

36. The wiring structure according to claim 30, wherein
the wiring layer is a power supply wiring layer provided with a power supply wiring and disposed on a back surface side of the semiconductor chip.

37. The wiring structure according to claim 30, wherein
a low dielectric constant insulating film made of a low dielectric constant material having a lower dielectric constant than AlN or BN is provided between the wiring portion and the wiring layer insulating film made of AlN or BN.

38. The wiring structure according to claim 30, wherein
the wiring layer is a power supply wiring layer provided with a pair of power supply wirings,
an MIM capacitor is provided in the power supply wiring layer, and
the MIM capacitor includes a dielectric layer made of the same material as the wiring layer insulating film.

39. The wiring structure according to claim 38, wherein
the MIM capacitor is composed of disposing the pair of power supply wirings face each other with the dielectric layer sandwiched therebetween.

40. A semiconductor device comprising:
a first semiconductor substrate including a multi-layer wiring layer, a first bonding insulating film made of AlN on an uppermost layer of the multi-layer wiring layer, and a first electrode pad formed on a surface of the first bonding insulating film; and
a second semiconductor substrate including a second bonding insulating film made of AlN and a second electrode pad formed on a surface of the second bonding insulating film, the first bonding insulating film being directly bonded to the second bonding insulating film and the first electrode pad being directly bonded to the second electrode pad.

41. A semiconductor device comprising:
a silicon substrate having an element layer on a surface thereof;
a multi-layer wiring layer formed on the element layer and including a wiring provided in a wiring layer insulating film made of AlN;
a power supply wiring layer formed on a back surface of the silicon substrate and including a power supply wiring provided in the wiring layer insulating film;
a bonding layer formed on the multi-layer wiring layer; and
a Si carrier directly bonded to the bonding layer, wherein
one or both of the wiring layer insulating film and the bonding layer are made of AlN.

42. A method for manufacturing a semiconductor device, comprising:
forming a bonding layer of AlN on a surface of a wiring layer insulating film of a multi-layer wiring layer provided on a semiconductor chip; and
directly bonding a surface of the bonding layer and a surface of a Si carrier after being activated.
